(19) United States
(12) Patent Application Publication
(10) Pub. No.: US 2023/0006161 A1
(43) Pub. Date: Jan. 5, 2023

(54) ORGANIC LIGHT-EMITTING DEVICE

(71) Applicant: LG CHEM, LTD., Seoul (KR)

(72) Inventors: Dongkeun SONG, Daejeon (KR); Jaegoo LEE, Daejeon (KR); Yongbum CHA, Daejeon (KR); Dong Uk HEO, Daejeon (KR); Woochul LEE, Daejeon (KR); Jiyoung NOH, Daejeon (KR); Jun Young LEE, Daejeon (KR)

(21) Appl. No.: 17/776,816

(22) PCT Filed: Jan. 28, 2021
(86) PCT No.: PCT/KR2021/001150

§ 371 Date: May 13, 2022

(30) Foreign Application Priority Data
Feb. 10, 2020 (KR) 10-2020-0015452

(51) Int. Cl. H01L 51/50; H01L 51/00

(52) U.S. Cl. CPC H01L 51/5004; H01L 51/0061; H01L 51/0052; H01L 51/006; H01L 51/0058; H01L 51/0067; H01L 51/0073; H01L 51/0074; H01L 51/0072; H01L 51/5012; H01L 51/5072; H01L 51/5092; H01L 51/5096; H01L 2251/552

(57) ABSTRACT

Provided is an organic light emitting device including an anode; a cathode; a light emitting layer between the anode and the cathode; a first organic material layer between the light emitting layer and the anode; and a second organic material layer between the light emitting layer and the cathode, wherein the first organic material layer comprises a compound of Chemical Formula 1, the light emitting layer comprises a compound of Chemical Formula 2, the second organic material layer comprises a compound of Chemical Formula 3, and Chemical Formula 1 and Chemical Formula 3 satisfy one or more of <Equation 1> to <Equation 3>:

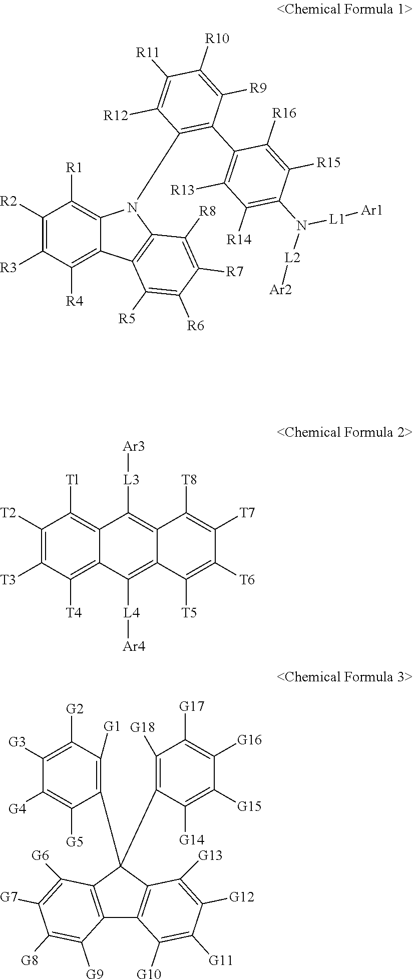

|E_{L1}|<E_{L3}| <Equation 1>

Eₛ₁>Eₛ₃ <Equation 2>

E_{T1}>E_{T3} <Equation 3>

### CROSS-REFERENCE TO RELATED APPLICATIONS

This application is a National Stage Application of International Application No. PCT/KR2021/001150 filed on Jan. 28, 2021, which claims priority to and the benefits of Korean Patent Application No. 10-2020-0015452, filed with the Korean Intellectual Property Office on Feb. 10, 2020, the entire contents of which are incorporated herein by reference.

### TECHNICAL FIELD

The present specification relates to an organic light emitting device.

### BACKGROUND

An organic light emission phenomenon generally refers to a phenomenon converting electrical energy to light energy using an organic material. An organic light emitting device using an organic light emission phenomenon normally has a structure including an anode, a cathode, and an organic material layer therebetween. Herein, the organic material layer is often formed in a multilayer structure formed with different materials in order to increase efficiency and stability of the organic light emitting device, and for example, can be formed with a hole injection layer, a hole transfer layer, a light emitting layer, an electron transfer layer, an electron injection layer and the like. When a voltage is applied between the two electrodes in such an organic light emitting device structure, holes and electrons are injected to the organic material layer from the anode and the cathode, respectively, and when the injected holes and electrons meet, excitons are formed, and light emits when these excitons fall back to the ground state.

Development of new materials for such an organic light emitting device has been continuously required.

### BRIEF DESCRIPTION

### Technical Problem

The present specification is directed to providing an organic light emitting device.

### Technical Solution

One embodiment of the present specification provides an organic light emitting device including an anode; a cathode; a light emitting layer provided between the anode and the cathode; a first organic material layer provided between the light emitting layer and the anode; and a second organic material layer provided between the light emitting layer and the cathode, wherein the first organic material layer includes a compound of the following Chemical Formula 1, the light emitting layer includes a compound of the following Chemical Formula 2, the second organic material layer includes a compound of the following Chemical Formula 3,

and Chemical Formula 1 and Chemical Formula 3 satisfy any one or more of the following <Equation 1> to <Equation 3>:

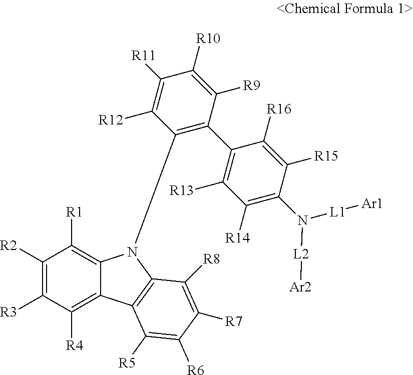

wherein in Chemical Formula 1:

L1 and L2 are the same as or different from each other, and each independently is a direct bond or a substituted or unsubstituted arylene group;

Ar1 and Ar2 are the same as or different from each other, and each independently is deuterium, a halogen group, a cyano group, a substituted or unsubstituted alkyl group, a substituted or unsubstituted cycloalkyl group, a substituted or unsubstituted silyl group, or a substituted or unsubstituted aryl group; and

R1 to R16 are the same as or different from each other, and each independently is hydrogen or deuterium, or adjacent groups among R1 to R8 bond to each other to form a substituted or unsubstituted ring;

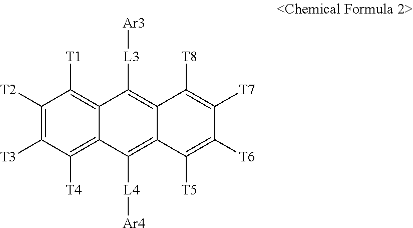

wherein in Chemical Formula 2:

L3 and L4 are the same as or different from each other, and each independently is a direct bond or a substituted or unsubstituted arylene group;

Ar3 and Ar4 are the same as or different from each other, and each independently is deuterium or a substituted or unsubstituted aryl group; and

T1 to T8 are the same as or different from each other, and each independently is hydrogen, deuterium, or a substituted or unsubstituted aryl group;

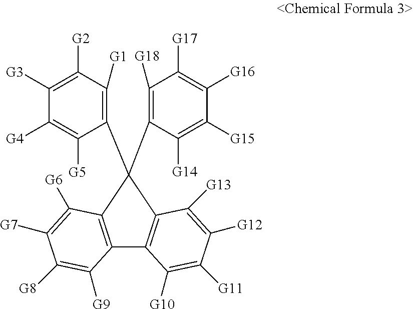

wherein in Chemical Formula 3:

at least one of G1 to G18 is -L5-Ar5, and the rest are hydrogen, or G1 and G18 are linked through -L51- to form a substituted or unsubstituted ring;

L5 is a direct bond or a substituted or unsubstituted arylene group;

Ar5 is a substituted or unsubstituted aryl group or a substituted or unsubstituted heteroaryl group; and

L51 is O or S;

|E_{L1}|<|E_{L3}| <Equation 1>

Eₛ₁>Eₛ₃ <Equation 2>

E_{T1}>E_{T3} <Equation 3>

wherein in Equations 1 to 3:

E_{L1} means a LUMO energy level (eV) of the compound of Chemical Formula 1;

E_{L3} means a LUMO energy level (eV) of the compound of Chemical Formula 3;

Eₛ₁ means a singlet energy (eV) of the compound of Chemical Formula 1;

Eₛ₃ means a singlet energy (eV) of the compound of Chemical Formula 3;

E_{T1} means a triplet energy (eV) of the compound of Chemical Formula 1; and

E_{T3} means a triplet energy (eV) of the compound of Chemical Formula 3.

### Advantageous Effects

An organic light emitting device according to one embodiment of the present specification includes a compound of Chemical Formula 1 between a light emitting layer and an anode, includes a compound of Chemical Formula 2 in the light emitting layer, and includes a compound of Chemical Formula 3 between the light emitting layer and a cathode, and as a result, low driving voltage and enhanced light efficiency are obtained.

### DESCRIPTION OF THE DRAWINGS

FIG. 1 and FIG. 2 illustrate examples of an organic light emitting device according to one embodiment of the present specification.

### REFERENCE NUMERALS

1: Substrate
2: Anode
3: First Organic Material Layer
4: Light Emitting Layer
5: Second Organic Material Layer
6: Cathode
7: Hole Injection Layer
8: Hole Transfer Layer
9: Electron Blocking Layer
10: Hole Blocking Layer
11: Electron Injection and Transfer Layer

### DETAILED DESCRIPTION

Hereinafter, the present specification will be described in more detail.

In the present specification, a description of a certain part “including” certain constituents means capable of further including other constituents, and does not exclude other constituents unless particularly stated on the contrary.

In the present specification, a description of a certain member being placed “on” another member includes not only a case of the one member being in contact with the another member but a case of still another member being present between the two members.

In the present specification, the “layer” has a meaning compatible with a ‘film’ mainly used in the art, and means coating covering a target area. The size of the “layer” is not limited, and each “layer” can have the same or a different size. According to one embodiment, the size of the “layer” can be the same as the whole device, can correspond to the size of a specific functional area, or can be as small as a single sub-pixel.

In the present specification, a meaning of a specific A material being included in a B layer includes both i) one or more types of A materials being included in one B layer, and ii) a B layer being famed in one or more layers, and an A material being included in one or more of the B layers that is a multilayer.

In the present specification, a meaning of a specific A material being included in a C layer or a D layer includes both i) being included in one or more layers of one or more C layers, ii) being included in one or more layers of one or more D layers, or iii) being included in each of one or more C layers and one or more D layers.

In the present specification, “or” refers to inclusive ‘or’, and does not refer to exclusive ‘or’. For example, condition A or B is satisfied by any one of the following: A is true (or present) and B is false (or not present), A is false (or not present) and B is true (or present), and A and B are all true (or present).

In the present specification, a “mixture thereof” or “mix” means including two or more types of materials. The “mixture” or “mix” can include a uniformly and/or non-uniformly mixed state, a dissolved state, a uniformly and/or non-uniformly dispersed state, and the like, but is not limited thereto.

Unless defined otherwise in the present specification, all technological and scientific terms used in the present specification have the same meanings as terms commonly understood by those skilled in the art. Although methods and materials similar or equivalent to those described in the present specification can be used in carrying out or experimenting embodiments of the present disclosure, suitable methods and materials are described later. All publications, patent applications, patents and other reference documents mentioned in the present specification are incorporated by reference in the present specification as a whole, and when conflicting, the present specification including definitions has priority unless specific passage is mentioned. Furthermore, materials, methods and examples are for illustrative purposes only, and not to limit the present specification.

Examples of substituents in the present specification are described below, however, the substituents are not limited thereto.

In the present specification,

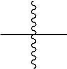

means a linking site.

The tam “substitution” means a hydrogen atom bonding to a carbon atom of a compound being changed to another substituent, and the position of substitution is not limited as long as it is a position at which the hydrogen atom is substituted, that is, a position at which a substituent can substitute, and when two or more substituents substitute, the two or more substituents can be the same as or different from each other.

In the present specification, the term “substituted or unsubstituted” means being substituted with one or more substituents selected from the group consisting of deuterium; a halogen group; a hydroxyl group; a cyano group; a nitro group; an alkyl group; a cycloalkyl group; an alkoxy group; an alkenyl group; a haloalkyl group; a silyl group; a boron group; an amine group; an aryl group; and a heteroaryl group, or being substituted with a substituent linking two or more substituents among the substituents illustrated above, or having no substituents.

In the present specification, linking two or more substituents refers to linking hydrogen of any one substituent to another substituent. For example, linking two or more substituents can include a phenyl group and a naphthyl group being linked to become a substituent of

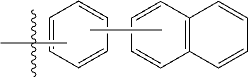

or

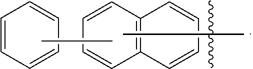

In addition, linking three substituents includes not only continuously linking (substituent 1)-(substituent 2)-(substituent 3), but also linking (substituent 2) and (substituent 3) to (substituent 1). For example, a phenyl group, a naphthyl group and an isopropyl group can be linked to become a substituent of

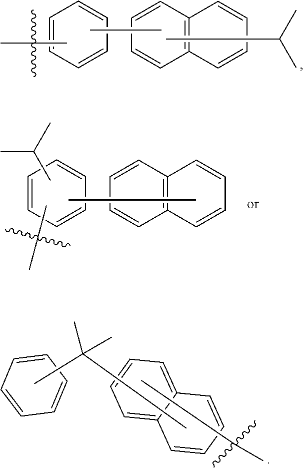

The same rule described above applies to cases of linking four or more substituents.

In the present specification, examples of the halogen group can include fluorine, chlorine, bromine or iodine.

In the present specification, the alkyl group can be linear or branched, and although not particularly limited thereto, the number of carbon atoms is preferably from 1 to 30. Specific examples thereof can include methyl, ethyl, propyl, n-propyl, isopropyl, butyl, n-butyl, isobutyl, tert-butyl, sec-butyl, 1-methyl-butyl, 1-ethyl-butyl, pentyl, n-pentyl, isopentyl, neopentyl, tert-pentyl, hexyl, n-hexyl, 1-methylpentyl, 2-methylpentyl, 4-methyl-2-pentyl, 3,3-dimethylbutyl, 2-ethylbutyl, heptyl, n-heptyl, 1-methylhexyl, cyclopentylmethyl, cyclohexylmethyl, octyl, n-octyl, tert-octyl, 1-methylheptyl, 2-ethylhexyl, 2-propylpentyl, n-nonyl, 2,2-dimethylheptyl, 1-ethyl-propyl, 1,1-dimethyl-propyl, isohexyl, 2-methylpentyl, 4-methylhexyl, 5-methylhexyl and the like, but are not limited thereto.

In the present specification, the cycloalkyl group is not particularly limited, but preferably has 3 to 30 carbon atoms. Specific examples thereof can include cyclopropyl, cyclobutyl, cyclopentyl, 3-methylcyclopentyl, 2,3-dimethylcyclopentyl, cyclohexyl, 3-methylcyclohexyl, 4-methylcyclohexyl, 2,3-dimethylcyclohexyl, 3,4,5-trimethylcyclohexyl, 4-tert-butylcyclohexyl, cycloheptyl, cyclooctyl, an adamantyl group and the like, but are not limited thereto.

In the present specification, the alkoxy group can be linear, branched or cyclic. The number of carbon atoms of the alkoxy group is not particularly limited, but is preferably from 1 to 30. Specific examples thereof can include methoxy, ethoxy, n-propoxy, isopropoxy, n-butoxy, isobutoxy, tert-butoxy, sec-butoxy, n-pentyloxy, neopentyloxy, isopentyloxy, n-hexyloxy, 3,3-dimethylbutyloxy, 2-ethylbutyloxy, n-octyloxy, n-nonyloxy, n-decyloxy, benzyloxy, p-methylbenzyloxy and the like, but are not limited thereto.

In the present specification, the alkenyl group can be linear or branched, and although not particularly limited thereto, the number of carbon atoms is preferably from 2 to 30. Specific examples thereof can include vinyl, 1-propenyl, isopropenyl, 1-butenyl, 2-butenyl, 3-butenyl, 1-pentenyl, 2-pentenyl, 3-pentenyl, 3-methyl-1-butenyl, 1,3-butadienyl, allyl, 1-phenylvinyl-1-yl, 2-phenylvinyl-1-yl, 2,2-diphenylvinyl-1-yl, 2-phenyl-2-(naphthyl-1-yl)vinyl-1-yl, 2,2-bis(diphenyl-1-yl)vinyl-1-yl, a stilbenyl group, a styrenyl group and the like, but are not limited thereto.

In the present specification, the haloalkyl group means, in the definition of the alkyl group, hydrogen of the alkyl group being substituted with at least one halogen group.

In the present specification, the aryl group is not particularly limited, but preferably has 6 to 30 carbon atoms, and the aryl group can be monocyclic or polycyclic.

When the aryl group is a monocyclic aryl group, the number of carbon atoms is not particularly limited, but is preferably from 6 to 30. Specific examples of the monocyclic aryl group can include a phenyl group, a biphenyl group, a terphenyl group and the like, but are not limited thereto.

When the aryl group is a polycyclic aryl group, the number of carbon atoms is not particularly limited, but is preferably from 10 to 30. Specific examples of the polycyclic aryl group can include a naphthyl group, an anthracene group, a phenanthrene group, a triphenylene group, a pyrene group, a phenalene group, a perylene group, a chrysene group, a fluorene group and the like, but are not limited thereto.

In the present specification, the fluorene group can be substituted, and adjacent groups can bond to each other to form a ring.

When the fluorene group is substituted,

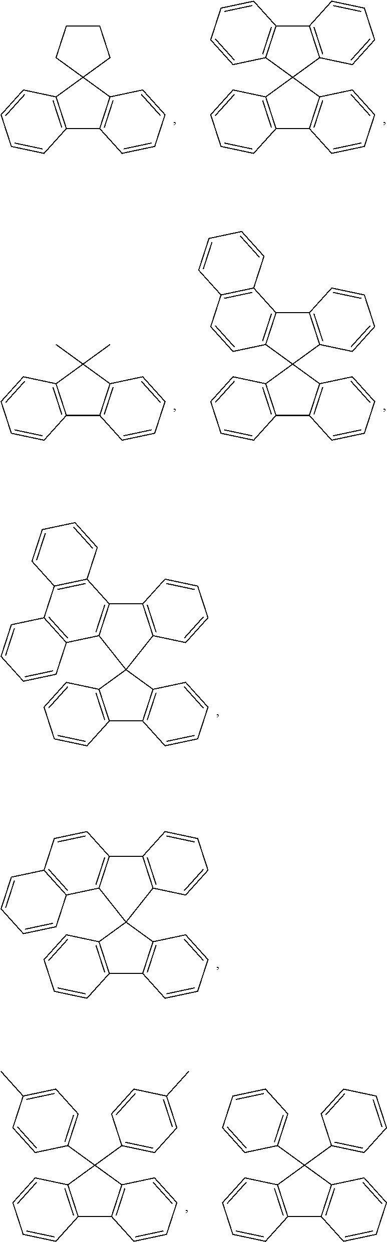

and the like can be included, however, the structure is not limited thereto.

In the present specification, an “adjacent” group can mean a substituent substituting an atom directly linked to an atom substituted by the corresponding substituent, a substituent sterically most closely positioned to the corresponding substituent, or another substituent substituting an atom substituted by the corresponding substituent. For example, two substituents substituting ortho positions in a benzene ring, and two substituents substituting the same carbon in an aliphatic ring can be interpreted as groups “adjacent” to each other.

In the present specification, the heteroaryl group is a group including one or more atoms that are not carbon, that is, heteroatoms, and specifically, the heteroatom can include one or more atoms selected from the group consisting of O, N, Se, S and the like. The number of carbon atoms is not particularly limited, but is preferably from 2 to 30, and the heteroaryl group can be monocyclic or polycyclic. Examples of the heteroaryl group can include a thiophene group, a furan group, a pyrrole group, an imidazole group, a thiazole group, an oxazole group, an oxadiazole group, a pyridine group, a bipyridine group, a pyrimidine group, a triazine group, a triazole group, an acridine group, a pyridazine group, a pyrazine group, a quinoline group, a quinazoline group, a quinoxaline group, a phthalazine group, a pyridopyrimidine group, a pyridopyrazine group, a pyrazinopyrazine group, an isoquinoline group, an indole group, a carbazole group, a benzoxazole group, a benzimidazole group, a benzothiazole group, a benzocarbazole group, a benzothiophene group, a dibenzothiophene group, a benzofuran group, a phenanthridine group, a phenanthroline group, an isoxazole group, a thiadiazole group, a dibenzofuran group, dibenzosilole group, a phenoxanthine group, a phenoxazine group, a phenothiazine group, a dihydroindenocarbazole group, a spirofluorenexanthene group, a spirofluorenethioxanthene group and the like, but are not limited thereto.

In the present specification, the silyl group can be an alkylsilyl group, an arylsilyl group, a heteroarylsilyl group or the like. As the alkyl group in the alkylsilyl group, the examples of the alkyl group described above can be applied, and as the aryl group in the arylsilyl group, the examples of the aryl group described above can be applied, and as the heteroaryl group in the heteroarylsilyl group, the examples of the heteroaryl group can be applied.

In the present specification, the boron group can be -BR₁₀₀R₁₀₁. R₁₀₀ and R₁₀₁ are the same as or different from each other, and can be each independently selected from the group consisting of hydrogen; deuterium; halogen; a nitrile group; a substituted or unsubstituted monocyclic or polycyclic cycloalkyl group having 3 to 30 carbon atoms; a substituted or unsubstituted linear or branched alkyl group having 1 to 30 carbon atoms; a substituted or unsubstituted monocyclic or polycyclic aryl group having 6 to 30 carbon atoms; and a substituted or unsubstituted monocyclic or polycyclic heteroaryl group having 2 to 30 carbon atoms. Specific examples of the boron group can include a trimethylboron group, a triethylboron group, a t-butyldimethylboron group, a triphenylboron group, a phenylboron group and the like, but are not limited thereto.

In the present specification, the amine group can be selected from the group consisting of —NH₂, an alkylamine group, an N-alkylarylamine group, an arylamine group, an N-arylheteroarylamine group, an N-alkylheteroarylamine group and a heteroarylamine group, and although not particularly limited thereto, the number of carbon atoms is preferably from 1 to 30. Specific examples of the amine group can include a methylamine group, a dimethylamine group, an ethylamine group, a diethylamine group, a phenylamine group, a naphthylamine group, a biphenylamine group, an anthracenylamine group, a 9-methyl-anthracenylamine group, a diphenylamine group, a ditolylamine group, an N-phenyltolylamine group, a triphenylamine group, an N-phenylbiphenylamine group, an N-phenylnaphthylamine group, an N-biphenylnaphthylamine group, an N-naphthylfluorenylamine group, an N-phenylphenanthrenylamine group, an N-biphenyl-phenanthrenylamine group, an N-phenylfluorenylamine group, an N-phenylterphenylamine group, an N-phenanthrenylfluorenyl-amine group, an N-biphenylfluorenylamine group and the like, but are not limited thereto.

In the present specification, the N-alkylarylamine group means an amine group in which N of the amine group is substituted with an alkyl group and an aryl group. The alkyl group and the aryl group in the N-alkylarylamine group are the same as the examples of the alkyl group and the aryl group described above.

In the present specification, the N-arylheteroarylamine group means an amine group in which N of the amine group is substituted with an aryl group and a heteroaryl group. The aryl group and the heteroaryl group in the N-arylheteroarylamine group are the same as the examples of the aryl group and the heteroaryl group described above.

In the present specification, the N-alkylheteroarylamine group means an amine group in which N of the amine group is substituted with an alkyl group and a heteroaryl group. The alkyl group and the heteroaryl group in the N-alkylheteroarylamine group are the same as the examples of the alkyl group and the heteroaryl group described above.

In the present specification, examples of the alkylamine group include a substituted or unsubstituted monoalkylamine group, or a substituted or unsubstituted dialkylamine group. The alkyl group in the alkylamine group can be a linear or branched alkyl group. The alkylamine group including two or more alkyl groups can include linear alkyl groups, branched alkyl groups, or both linear alkyl groups and branched alkyl groups. For example, the alkyl group in the alkylamine group can be selected from among the examples of the alkyl group described above.

In the present specification, examples of the arylamine group include a substituted or unsubstituted monoarylamine group, or a substituted or unsubstituted diarylamine group. The aryl group in the arylamine group can be a monocyclic aryl group or a polycyclic aryl group. The arylamine group including two or more aryl groups can include monocyclic aryl groups, polycyclic aryl groups, or both monocyclic aryl groups and polycyclic aryl groups. For example, the aryl group in the arylamine group can be selected from among the examples of the aryl group described above.

In the present specification, examples of the heteroarylamine group include a substituted or unsubstituted monoheteroarylamine group, or a substituted or unsubstituted diheteroarylamine group. The heteroarylamine group including two or more heteroaryl groups can include monocyclic heteroaryl groups, polycyclic heteroaryl groups, or both monocyclic heteroaryl groups and polycyclic heteroaryl groups. For example, the heteroaryl group in the heteroarylamine group can be selected from among the examples of the heteroaryl group described above.

In the present specification, the meaning of “adjacent two of the substituents bonding to each other to form a ring” is adjacent groups bonding to each other to form a substituted or unsubstituted hydrocarbon ring; or a substituted or unsubstituted heteroring.

In the present specification, the “ring” in the substituted or unsubstituted ring formed by bonding to each other means a substituted or unsubstituted hydrocarbon ring; or a substituted or unsubstituted heteroring.

In the present specification, the hydrocarbon ring can be an aromatic hydrocarbon ring, an aliphatic hydrocarbon ring, or a fused ring of aromatic hydrocarbon and aliphatic hydrocarbon, and can be selected from among the examples of the cycloalkyl group and the aryl group except for those that are not monovalent.

In the present specification, the heteroring includes one or more atoms that are not carbon, that is, heteroatoms, and specifically, the heteroatom can include one or more atoms selected from the group consisting of O, N, Se, S and the like. The heteroring can be monocyclic or polycyclic, can be aromatic, aliphatic, or a fused ring of aromatic and aliphatic, and the aromatic heteroring can be selected from among the examples of the heteroaryl group except for those that are not monovalent.

In the present specification, the aliphatic heteroring means an aliphatic ring including one or more of heteroatoms. Examples of the aliphatic heteroring can include oxirane, tetrahydrofuran, 1,4-dioxane, pyrrolidine, piperidine, morpholine, oxepane, azokane, thiokane and the like, but are not limited thereto.

In the present specification, the arylene group means the aryl group having two bonding sites, that is, a divalent group. The descriptions on the aryl group provided above can be applied thereto except for those that are each a divalent group.

In the present specification, the heteroarylene group means the heteroaryl group having two bonding sites, that is, a divalent group. The descriptions on the heteroaryl group provided above can be applied thereto except for those that are each a divalent group.

An organic light emitting device according to one embodiment of the present specification includes an anode; a cathode; a light emitting layer provided between the anode and the cathode; a first organic material layer provided between the light emitting layer and the anode; and a second organic material layer provided between the light emitting layer and the cathode, wherein the first organic material layer includes a compound of Chemical Formula 1, the light emitting layer includes a compound of Chemical Formula 2, the second organic material layer includes a compound of Chemical Formula 3, and Chemical Formula 1 and Chemical Formula 3 satisfy any one or more of [Equation 1] to [Equation 3]. When Chemical Formula 1 and Chemical Formula 3 satisfy any one of more of [Equation 1] to [Equation 3], an effect of superior light emission efficiency is obtained in the organic light emitting device.

The organic light emitting device according to the embodiment includes the compound of Chemical Formula 1 between the anode and the light emitting layer, that is, in the first organic material layer, includes the compound of Chemical Formula 2 in the light emitting layer, and includes the compound of Chemical Formula 3 between the cathode and the light emitting layer, that is, in the second organic material layer. By the first organic material layer of the organic light emitting device including the compound of Chemical Formula 1, hole injection and transfer become fast, and carrier transport into the light emitting layer is maximized, which can increase efficiency of the light emitting layer. By the second organic material layer including the compound of Chemical Formula 3, efficiency of the light emitting layer can increase by facilitating electron injection and transfer to the light emitting layer, and by the light emitting layer including the compound of Chemical Formula 2, mobility of electrons and holes transferred to the light emitting layer is enhanced and structural properties of improving molecular stability are obtained. As a result, a device with low voltage and high efficiency can be obtained.

According to one embodiment of the present specification, the first organic material layer is provided in contact with the light emitting layer.

According to one embodiment of the present specification, the first organic material layer includes an electron blocking layer, and the electron blocking layer includes the compound of Chemical Formula 1.

According to one embodiment of the present specification, the light emitting layer includes a dopant.

According to one embodiment of the present specification, the light emitting layer includes a fluorescent dopant.

According to one embodiment of the present specification, the fluorescent dopant can include an arylamine-based dopant, a boron-based dopant, and a mixture thereof.

As the arylamine-based dopant and the boron-based dopant, those used in the art can be used without limit.

According to one embodiment of the present specification, the light emitting layer is a single layer.

According to one embodiment of the present specification, the dopant is a blue dopant.

According to one embodiment of the present specification, the light emitting layer is a blue light emitting layer.

According to one embodiment of the present specification, the organic light emitting device has a maximum emission wavelength (λₘₐₓ) of 400 nm to 470 nm in a light emission spectrum.

According to one embodiment of the present specification, the light emitting layer further includes a compound different from the compound of Chemical Formula 2.

According to one embodiment of the present specification, the light emitting layer includes a mixed host of two or more types, and one or more types of the mixed host of two or more types include the compound of Chemical Formula 2.

According to one embodiment of the present specification, the light emitting layer includes a mixed host of two or more types, and at least one type of the mixed host of two or more types includes the compound of Chemical Formula 2, and the rest include a compound different from the compound of Chemical Formula 2.

At least one type of the mixed host of two or more types includes the compound of Chemical Formula 2, and as the rest, anthracene-based hosts used in the art can be used without limit as long as they are different from Chemical Formula 2, however, the rest are not limited thereto.

The organic light emitting device using a mixed host of two or more types according to one embodiment of the present specification is intended to enhance device performance by mixing advantages of each host. For example, when mixing two types of hosts, an organic light emitting device having effects of high efficiency, low voltage and long lifetime can be manufactured by mixing one type of host having effects of high efficiency and low voltage and one type of host having an effect of long lifetime.

According to one embodiment of the present specification, the light emitting layer includes a host and a dopant.

According to one embodiment of the present specification, the light emitting layer includes a host and a dopant, and includes the compound of Chemical Formula 2 as the host and the fluorescent dopant as the dopant.

According to one embodiment of the present specification, the light emitting layer includes a host and a dopant, includes a mixed host of two or more types as the host. At least one type of the mixed host of two or more types includes the compound of Chemical Formula 2, and the rest include a compound different from the compound of Chemical Formula 2, and as the dopant, the fluorescent dopant is included.

According to one embodiment of the present specification, the light emitting layer includes a host and a dopant, and the light emitting layer includes the host:the dopant in a weight ratio of 99.9:0.1 to 80:20.

According to one embodiment of the present specification, the light emitting layer includes a host and a dopant, and the light emitting layer includes the host:the dopant in a volume ratio of 99.9:0.1 to 80:20.

According to one embodiment of the present specification, one or more organic material layers are included between the second organic material layer and the light emitting layer. The organic material layer includes a hole blocking layer.

According to one embodiment of the present specification, one or more organic material layers are included between the second organic material layer and the cathode. The organic material layer includes an electron injection layer.

According to one embodiment of the present specification, the second organic material layer includes an electron transfer layer, and the electron transfer layer includes the compound of Chemical Formula 3.

According to one embodiment of the present specification, the second organic material layer includes an electron injection and transfer layer, and the electron injection and transfer layer includes the compound of Chemical Formula 3.

According to one embodiment of the present specification, the organic material layer includes the compound of Chemical Formula 3, an organic alkali metal complex compound, and a mixture thereof. Herein, examples of the organic alkali metal complex compound can include lithium quinolate and aluminum quinolate, but are not limited thereto, and the organic alkali metal complex compound is included in a content of 10 wt % to 90 wt % and preferably 30 wt % to 70 wt % with respect to the material of the organic material layer.

In the present specification, the “energy level” means a size of energy. Accordingly, the energy level is interpreted to mean an absolute value of the corresponding energy value. For example, the energy level being low or deep means the absolute value increasing in a negative direction from a vacuum level.

In the present specification, a HOMO (highest occupied molecular orbital) means a molecular orbital function where electrons are in an area with highest energy among areas capable of participating in bonding, a LUMO (lowest unoccupied molecular orbital) means a molecular orbital function where electrons are in an area with lowest energy among anti-bonding areas, and a HOMO energy level means a distance from a vacuum level to the HOMO. In addition, a LUMO energy level means a distance from a vacuum level to the LUMO. A determined structure is needed in order to understand electron distribution in a molecule and to understand optical properties. In addition, an electron structure has different structures in neutral, anionic and cationic states depending on the state of charge of the molecule. Although energy levels in neutral, cationic and anionic states are all important in order to drive a device, HOMO (highest occupied molecular orbital) and LUMO (lowest unoccupied molecular orbital) in a neutral state are typically recognized as important properties. In order to determine a molecular structure of a chemical material, a density functional theory is used to optimize an input structure. For the DFT calculation, a BPW91 calculation method (Becke exchange and Perdew correlation-correlation functional) and a DNP (double numerical basis set including polarization functional) basis set are used. The BPW91 calculation method is described in the reference ‘A. D. Becke, Phys. Rev. A, 38, 3098 (1988)’ and ‘J. P. Perdew and Y. Wang, Phys. Rev. B, 45, 13244 (1992)’, and the DNP basis set is described in the reference ‘B. Delley, J. Chem. Phys., 92, 508 (1990)’.

‘DMol3’ package of Biovia can be used to perform calculations using the density functional theory. When an optimal molecular structure is determined using the given method, an energy level that electrons can occupy can be obtained as a result.

In the present specification, triplet energy means an electronic state with a spin quantum number of 1 in a molecule. As for the triplet energy, singlet and triplet energy levels are calculated using a time dependent density functional theory (TD-DFT) in order to obtain properties in an excited state for the optimal molecular structure determined using the above-described method. The density functional calculation can be performed using ‘Gaussian09’ package, a commercial calculation program developed by Gaussian, Inc. A B3PW91 calculation method (Becke exchange and Perdew correlation-correlation functional) and a 6-31G* basis set are used to calculate the time dependent density functional theory. The 6-31G* basis set is described in the reference ‘W. J. Hehre et al., J. Chem. Phys. 56, 2257 (1972)’. Energy obtained when electron arrangements are singlet and triplet for the optimal molecular structure determined using the density functional theory is calculated using a time dependent density functional theory (TD-DFT).

According to one embodiment of the present specification, in Chemical Formula 1, L1 and L2 are the same as or different from each other, and each independently a direct bond, or a substituted or unsubstituted monocyclic or polycyclic arylene group having 6 to 30 carbon atoms.

According to one embodiment of the present specification, in Chemical Formula 1, L1 and L2 are the same as or different from each other, and each independently is a direct bond, or a substituted or unsubstituted monocyclic or polycyclic arylene group having 6 to 20 carbon atoms.

According to one embodiment of the present specification, in Chemical Formula 1, L1 and L2 are the same as or different from each other, and each independently is a direct bond, or a monocyclic or polycyclic arylene group having 6 to 30 carbon atoms that is unsubstituted or substituted with deuterium or a linear or branched alkyl group having 1 to 30 carbon atoms.

According to one embodiment of the present specification, in Chemical Formula 1, L1 and L2 are the same as or different from each other, and each independently is a direct bond, or a monocyclic or polycyclic arylene group having 6 to 20 carbon atoms that is unsubstituted or substituted with deuterium or a linear or branched alkyl group having 1 to 20 carbon atoms.

According to one embodiment of the present specification, in Chemical Formula 1, L1 and L2 are the same as or different from each other, and each independently is a direct bond; a phenylene group that is unsubstituted or substituted with deuterium; a biphenylylene group; or a divalent fluorenyl group substituted with a methyl group.

According to one embodiment of the present specification, in Chemical Formula 1, Ar1 and Ar2 are the same as or different from each other, and each independently is deuterium, a halogen group, a cyano group, a substituted or unsubstituted linear or branched alkyl group having 1 to 30 carbon atoms, a substituted or unsubstituted linear or branched alkylsilyl group having 1 to 30 carbon atoms, or a substituted or unsubstituted monocyclic or polycyclic aryl group having 6 to 30 carbon atoms.

According to one embodiment of the present specification, in Chemical Formula 1, Ar1 and Ar2 are the same as or different from each other, and each independently is deuterium, a halogen group, a cyano group, a substituted or unsubstituted linear or branched alkyl group having 1 to 20 carbon atoms, a substituted or unsubstituted linear or branched alkylsilyl group having 1 to 20 carbon atoms, or a substituted or unsubstituted monocyclic or polycyclic aryl group having 6 to 20 carbon atoms.

According to one embodiment of the present specification, in Chemical Formula 1, Ar1 and Ar2 are the same as or different from each other, and each independently is deuterium, a halogen group, a cyano group, a linear or branched alkyl group having 1 to 30 carbon atoms, a linear or branched alkylsilyl group having 1 to 30 carbon atoms, or a monocyclic or polycyclic aryl group having 6 to 30 carbon atoms that is unsubstituted or substituted with deuterium, a halogen group, a cyano group, a linear or branched alkyl group having 1 to 30 carbon atoms, a linear or branched alkylsilyl group having 1 to 30 carbon atoms or a monocyclic or polycyclic aryl group having 6 to 30 carbon atoms.

According to one embodiment of the present specification, in Chemical Formula 1, Ar1 and Ar2 are the same as or different from each other, and each independently is deuterium, a halogen group, a cyano group, a linear or branched alkyl group having 1 to 20 carbon atoms, a linear or branched alkylsilyl group having 1 to 20 carbon atoms, or a monocyclic or polycyclic aryl group having 6 to 20 carbon atoms that is unsubstituted or substituted with deuterium, a halogen group, a cyano group, a linear or branched alkyl group having 1 to 20 carbon atoms, a linear or branched alkylsilyl group having 1 to 20 carbon atoms or a monocyclic or polycyclic aryl group having 6 to 20 carbon atoms.

According to one embodiment of the present specification, in Chemical Formula 1, Ar1 and Ar2 are the same as or different from each other, and each independently deuterium; F; a cyano group; a methyl group; a tert-butyl group; a trimethylsilyl group; a phenyl group that is unsubstituted or substituted with deuterium, a cyano group, F, a methyl group, a tert-butyl group or a trimethylsilyl group; a biphenyl group that is unsubstituted or substituted with deuterium; a naphthyl group; a phenanthrene group; a triphenylene group; a terphenyl group; a fluorene group substituted with a methyl group or a phenyl group; or a spirobifluorene group.

According to one embodiment of the present specification, in Chemical Formula 1, R1 to R16 are the same as or different from each other, and each independently is hydrogen or deuterium.

According to one embodiment of the present specification, in Chemical Formula 1, R1 to R16 are hydrogen.

According to one embodiment of the present specification, in Chemical Formula 1, R1 to R16 are deuterium.

According to one embodiment of the present specification, in Chemical Formula 1, adjacent groups among R1 to R8 bond to each other to form a substituted or unsubstituted aromatic hydrocarbon ring.

According to one embodiment of the present specification, in Chemical Formula 1, adjacent groups among R1 to R8 bond to each other to form a substituted or unsubstituted benzene ring.

According to one embodiment of the present specification, in Chemical Formula 1, adjacent groups among R1 to R8 bond to each other to form a benzene ring.

According to one embodiment of the present specification, in Chemical Formula 2, T1 to T8 are the same as or different from each other, and each independently is hydrogen, deuterium, or a substituted or unsubstituted monocyclic or polycyclic aryl group having 6 to 30 carbon atoms.

According to one embodiment of the present specification, in Chemical Formula 2, T1 to T8 are the same as or different from each other, and each independently is hydrogen, deuterium, or a substituted or unsubstituted monocyclic or polycyclic aryl group having 6 to 20 carbon atoms.

According to one embodiment of the present specification, in Chemical Formula 2, T1 to T8 are the same as or different from each other, and each independently is hydrogen, deuterium, or a monocyclic or polycyclic aryl group having 6 to 30 carbon atoms.

According to one embodiment of the present specification, in Chemical Formula 2, T1 to T8 are the same as or different from each other, and each independently is hydrogen, deuterium, or a monocyclic or polycyclic aryl group having 6 to 20 carbon atoms.

According to one embodiment of the present specification, in Chemical Formula 2, T1 to T8 are the same as or different from each other, and each independently is hydrogen, deuterium, a phenyl group, or a naphthyl group.

According to one embodiment of the present specification, in Chemical Formula 2, L3 and L4 are the same as or different from each other, and each independently is a direct bond or a substituted or unsubstituted monocyclic or polycyclic arylene group having 6 to 30 carbon atoms.

According to one embodiment of the present specification, in Chemical Formula 2, L3 and L4 are the same as or different from each other, and each independently is a direct bond or a substituted or unsubstituted monocyclic or polycyclic arylene group having 6 to 20 carbon atoms.

According to one embodiment of the present specification, in Chemical Formula 2, L3 and L4 are the same as or different from each other, and each independently is a direct bond or a monocyclic or polycyclic arylene group having 6 to 30 carbon atoms that is unsubstituted or substituted with deuterium.

According to one embodiment of the present specification, in Chemical Formula 2, L3 and L4 are the same as or different from each other, and each independently is a direct bond or a monocyclic or polycyclic arylene group having 6 to 20 carbon atoms that is unsubstituted or substituted with deuterium.

According to one embodiment of the present specification, in Chemical Formula 2, L3 and L4 are the same as or different from each other, and each independently is a direct bond or a phenylene group that is unsubstituted or substituted with deuterium.

According to one embodiment of the present specification, in Chemical Formula 2, Ar3 and Ar4 are the same as or different from each other, and each independently is deuterium or a substituted or unsubstituted monocyclic or polycyclic aryl group having 6 to 30 carbon atoms.

According to one embodiment of the present specification, in Chemical Formula 2, Ar3 and Ar4 are the same as or different from each other, and each independently is deuterium or a substituted or unsubstituted monocyclic or polycyclic aryl group having 6 to 20 carbon atoms.

According to one embodiment of the present specification, in Chemical Formula 2, Ar3 and Ar4 are the same as or different from each other, and each independently is deuterium or a monocyclic or polycyclic aryl group having 6 to 30 carbon atoms that is unsubstituted or substituted with deuterium.

According to one embodiment of the present specification, in Chemical Formula 2, Ar3 and Ar4 are the same as or different from each other, and each independently is deuterium or a monocyclic or polycyclic aryl group having 6 to 20 carbon atoms that is unsubstituted or substituted with deuterium.

According to one embodiment of the present specification, in Chemical Formula 2, Ar3 and Ar4 are the same as or different from each other, and each independently is deuterium; a phenyl group that is unsubstituted or substituted with deuterium; or a naphthyl group that is unsubstituted or substituted with deuterium.

According to one embodiment of the present specification, L51 is O.

According to one embodiment of the present specification, L51 is S.

According to one embodiment of the present specification, G1 and G18 are linked through -L51- to form a substituted or unsubstituted heteroring.

According to one embodiment of the present specification, G1 and G18 are linked through -L51- to form a substituted or unsubstituted dibenzofuran ring or a substituted or unsubstituted dibenzothiophene ring.

According to one embodiment of the present specification, G1 and G18 are linked through —O— to form a substituted or unsubstituted dibenzofuran ring.

According to one embodiment of the present specification, G1 and G18 are linked through —S— to form a substituted or unsubstituted dibenzothiophene ring.

According to one embodiment of the present specification, G1 and G18 are linked through —O— to form a dibenzofuran ring.

According to one embodiment of the present specification, G1 and G18 are linked through —S— to form a dibenzothiophene ring.

According to one embodiment of the present specification, in Chemical Formula 3, L5 is a direct bond or a substituted or unsubstituted monocyclic or polycyclic arylene group having 6 to 30 carbon atoms.

According to one embodiment of the present specification, in Chemical Formula 3, L5 is a direct bond or a substituted or unsubstituted monocyclic or polycyclic arylene group having 6 to 20 carbon atoms.

According to one embodiment of the present specification, in Chemical Formula 3, L5 is a direct bond or a monocyclic or polycyclic arylene group having 6 to 30 carbon atoms.

According to one embodiment of the present specification, in Chemical Formula 3, L5 is a direct bond or a monocyclic or polycyclic arylene group having 6 to 20 carbon atoms.

According to one embodiment of the present specification, in Chemical Formula 3, L5 is a direct bond or a phenylene group.

According to one embodiment of the present specification, in Chemical Formula 3, Ar5 is any one selected from among the following structures:

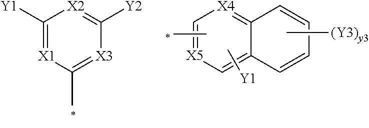

wherein in the structures:

* is a site bonding to L5 of Chemical Formula 3;

at least one of X1 to X3 is N, and the rest are CH;

at least one of X4 and X5 is N, and any remaining is CH;

Y1 to Y3 are the same as or different from each other, and each independently is hydrogen, deuterium, a substituted or unsubstituted alkyl group, a substituted or unsubstituted aryl group, or a substituted or unsubstituted heteroaryl group; and

y3 is an integer of 1 to 4, and when y3 is 2 or greater, the two or more Y3s are the same as or different from each other.

According to one embodiment of the present specification, any one of X1 to X3 is N, and the rest are CH.

According to one embodiment of the present specification, any two of X1 to X3 are N, and the remaining one is CH.

According to one embodiment of the present specification, X1 to X3 are N.

According to one embodiment of the present specification, any one of X4 and X5 is N, and any remaining is CH.

According to one embodiment of the present specification, X4 and X5 are N.

According to one embodiment of the present specification, Y1 and Y2 are the same as or different from each other, and each independently is a substituted or unsubstituted aryl group.

According to one embodiment of the present specification, Y1 and Y2 are the same as or different from each other, and each independently is a substituted or unsubstituted monocyclic or polycyclic aryl group having 6 to 30 carbon atoms.

According to one embodiment of the present specification, Y1 and Y2 are the same as or different from each other, and each independently is a substituted or unsubstituted monocyclic or polycyclic aryl group having 6 to 20 carbon atoms.

According to one embodiment of the present specification, Y1 and Y2 are the same as or different from each other, and each independently is a monocyclic or polycyclic aryl group having 6 to 30 carbon atoms that is unsubstituted or substituted with a cyano group, a linear or branched alkyl group having 1 to 30 carbon atoms or a monocyclic or polycyclic heteroaryl group having 2 to 30 carbon atoms.

According to one embodiment of the present specification, Y1 and Y2 are the same as or different from each other, and each independently is a monocyclic or polycyclic aryl group having 6 to 20 carbon atoms that is unsubstituted or substituted with a cyano group, a linear or branched alkyl group having 1 to 20 carbon atoms or a monocyclic or polycyclic heteroaryl group having 2 to 20 carbon atoms.

According to one embodiment of the present specification, Y1 and Y2 are the same as or different from each other, and each independently is a phenyl group that unsubstituted or substituted with a methyl group or a pyridine group; a biphenyl group that is unsubstituted or substituted with a cyano group; or a terphenyl group.

According to one embodiment of the present specification, Y3 is hydrogen.

According to one embodiment of the present specification, the compound of Chemical Formula 1 is any one compound selected from among the following compounds:

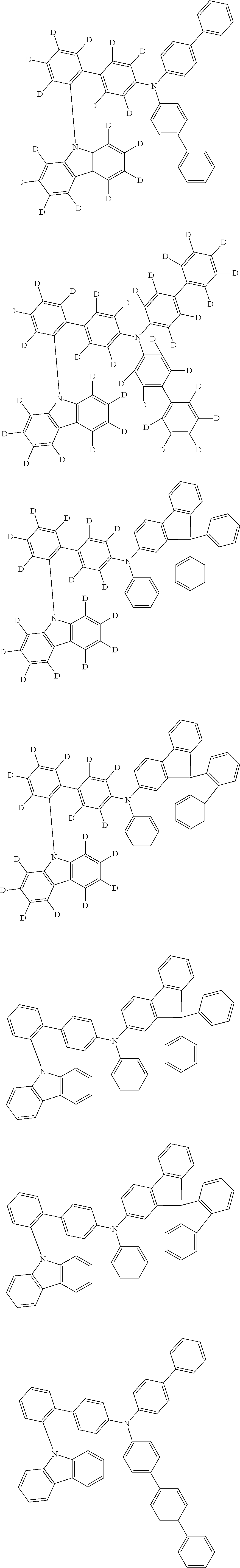

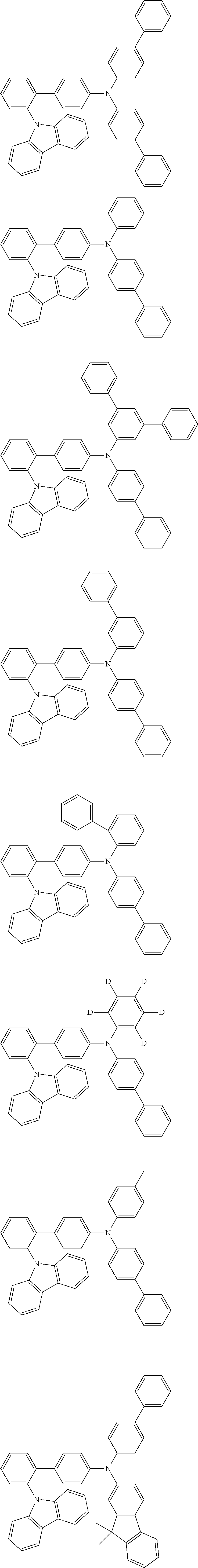

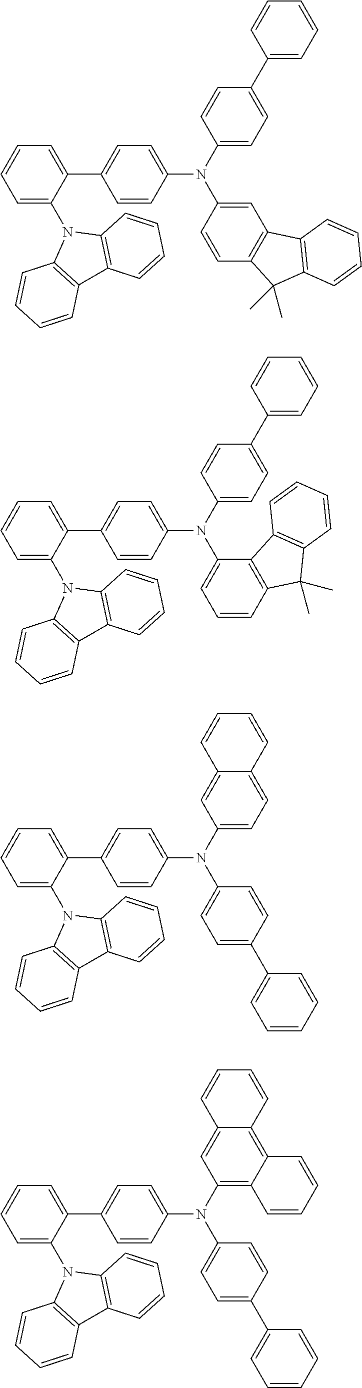

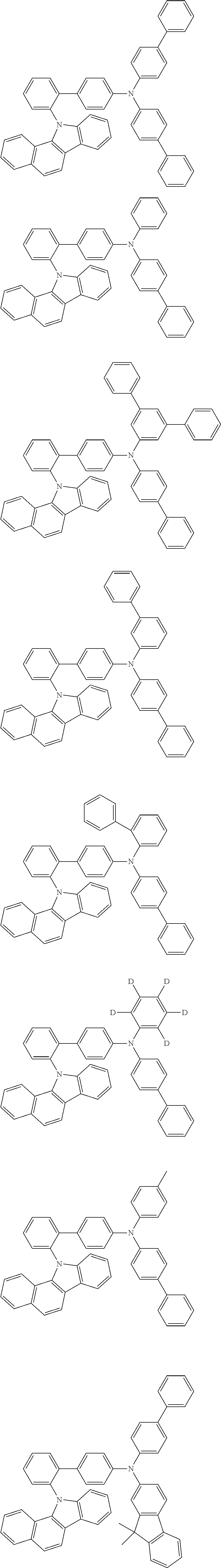

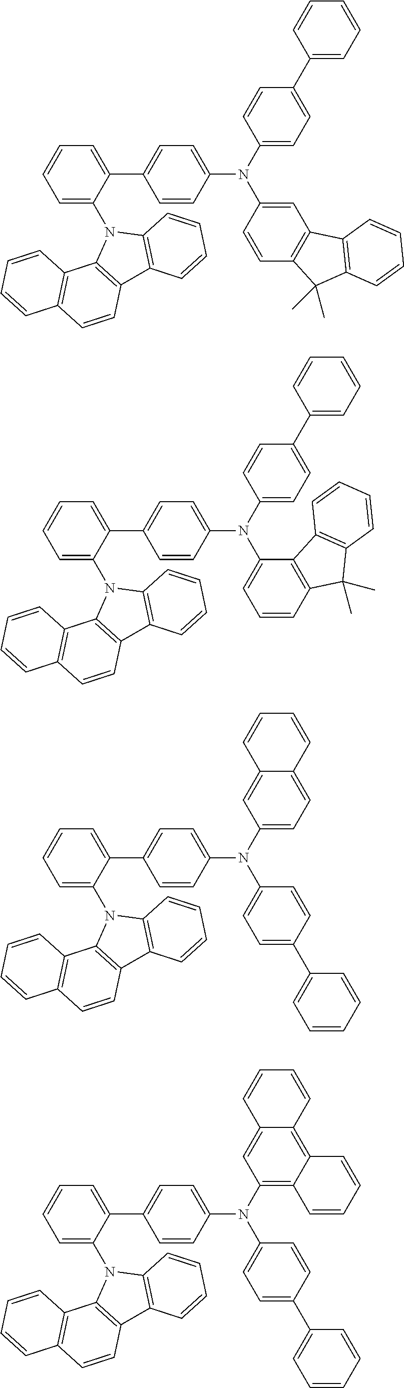

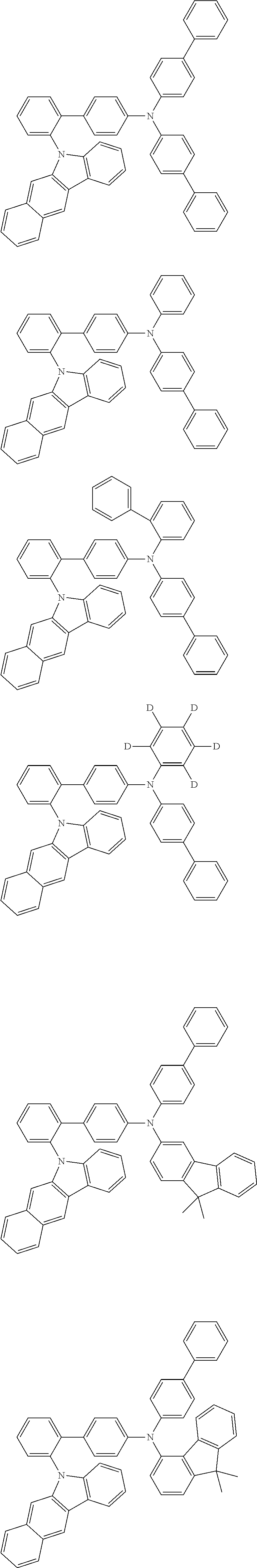

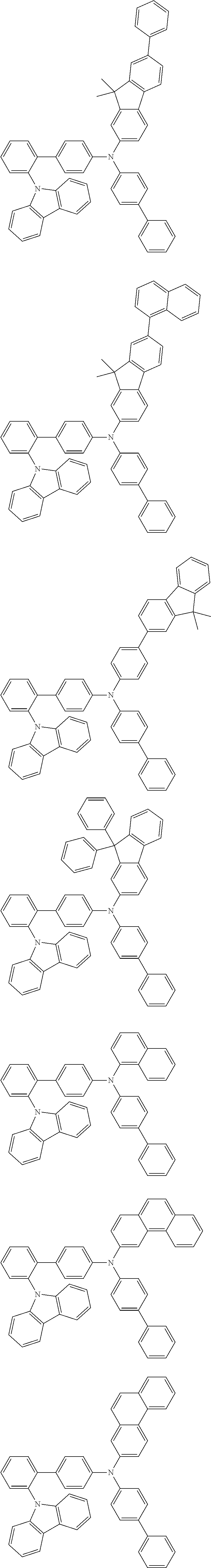

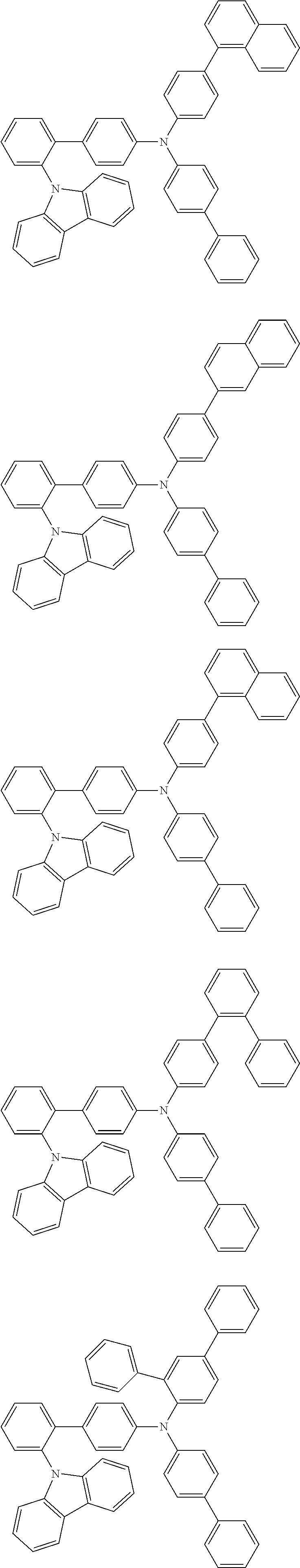

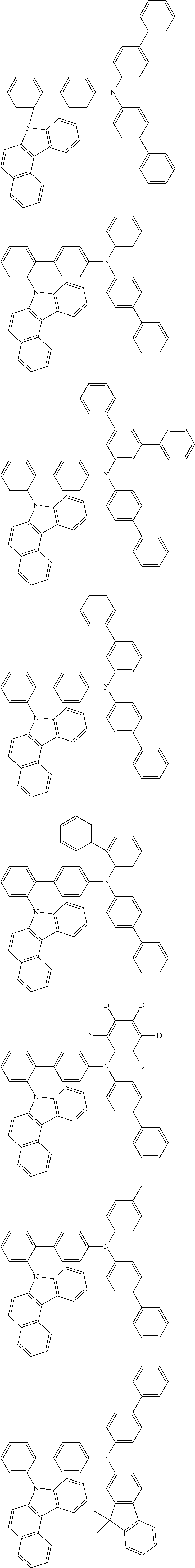

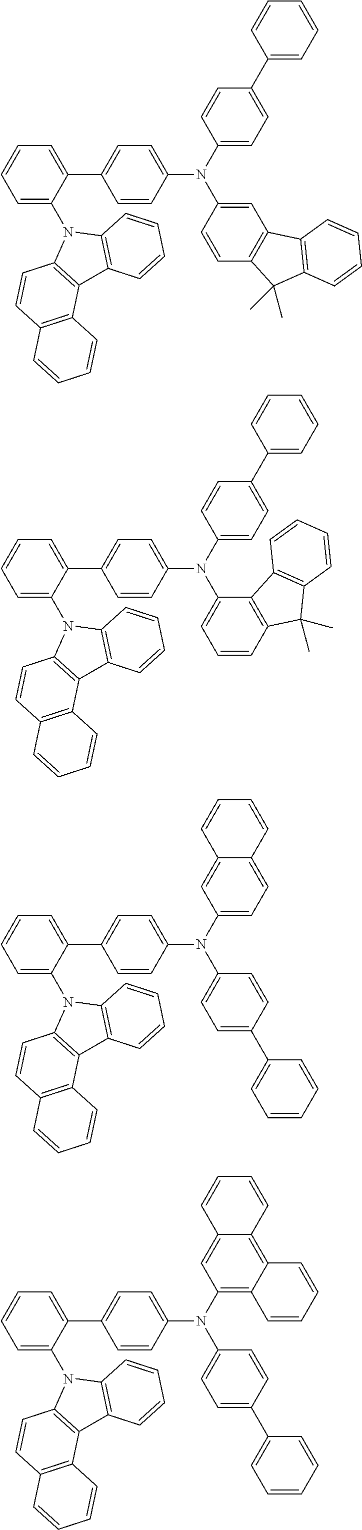 [SMILES: CC1(C)c2ccccc2-c2cc(N(c3ccc(-c4ccccc4)cc3)c3ccc(-c4ccccc4-n4c5ccccc5c5c6ccccc6ccc54)cc3)ccc21 ; CC1(C)c2ccccc2-c2c(N(c3ccc(-c4ccccc4)cc3)c3ccc(-c4ccccc4-n4c5ccccc5c5c6ccccc6ccc54)cc3)cccc21 ; c1ccc(-c2ccc(N(c3ccc(-c4ccccc4-n4c5ccccc5c5c6ccccc6ccc54)cc3)c3ccc4ccccc4c3)cc2)cc1 ; c1ccc(-c2ccc(N(c3ccc(-c4ccccc4-n4c5ccccc5c5c6ccccc6ccc54)cc3)c3cc4ccccc4c4ccccc34)cc2)cc1]

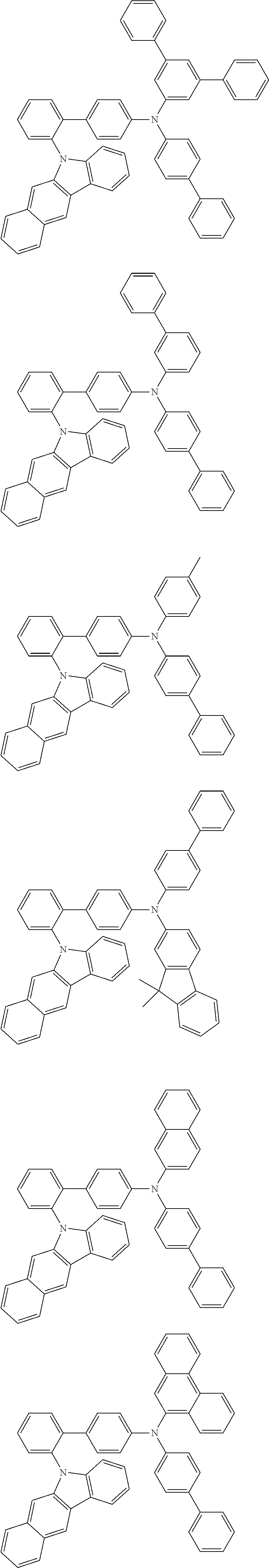

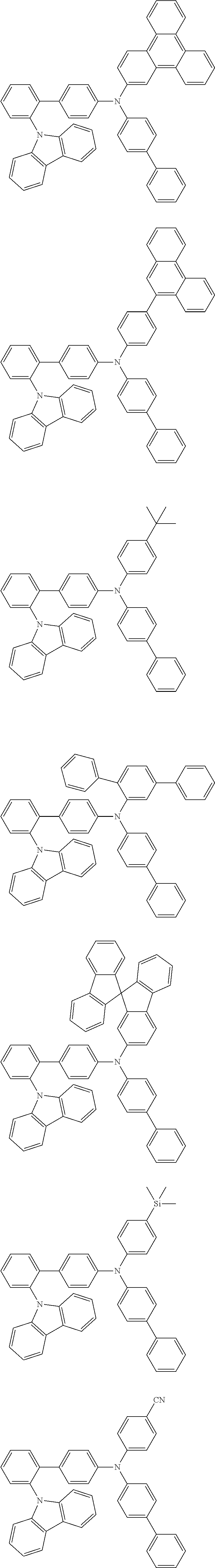

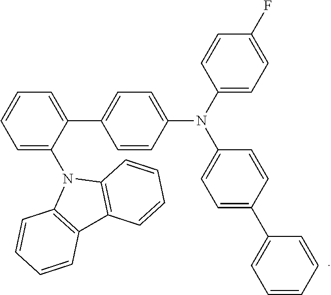 [SMILES: Fc1ccc(N(c2ccc(-c3ccccc3)cc2)c2ccc(-c3ccccc3-n3c4ccccc4c4ccccc43)cc2)cc1]

According to one embodiment of the present specification, the compound of Chemical Formula 2 is any one compound selected from among the following compounds:

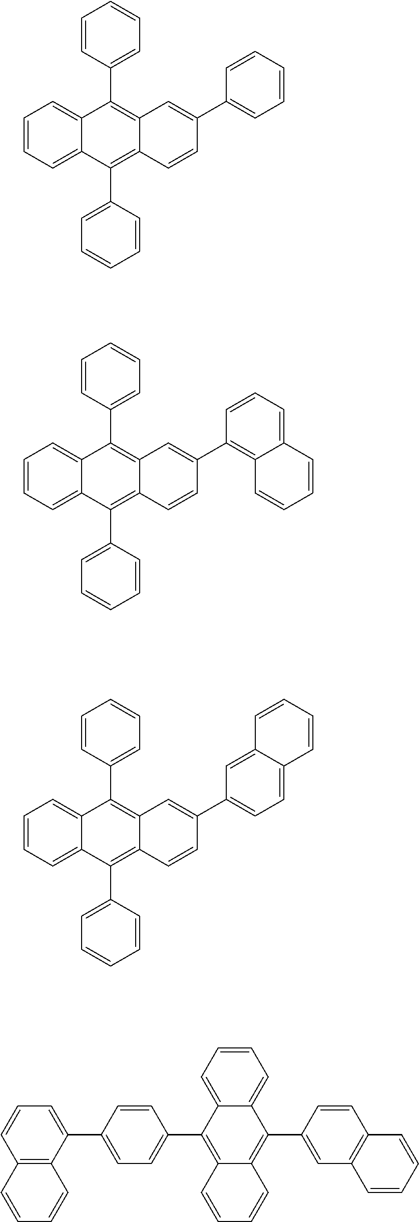

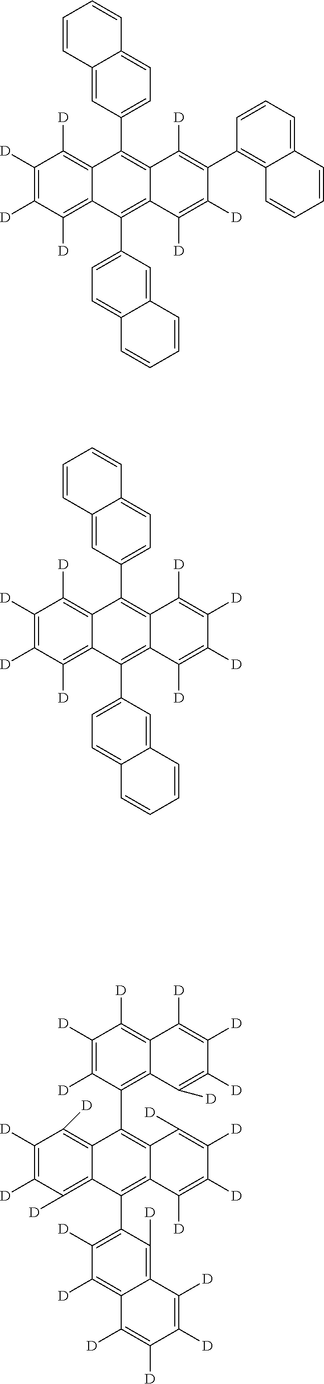 [SMILES: [2H]c1c([2H])c([2H])c2c(-c3ccc4ccccc4c3)c3c([2H])c(-c4cccc5ccccc45)c([2H])c([2H])c3c(-c3ccc4ccccc4c3)c2c1[2H] ; [2H]c1c([2H])c([2H])c2c(-c3ccc4ccccc4c3)c3c([2H])c([2H])c([2H])c([2H])c3c(-c3ccc4ccccc4c3)c2c1[2H] ; [2H]c1c([2H])c([2H])c2c([2H])c(-c3c4c([2H])c([2H])c([2H])c([2H])c4c(-c4c([2H])c([2H])c([2H])c5c([2H])c([2H])c([2H])c([2H])c45)c4c([2H])c([2H])c([2H])c([2H])c34)c([2H])c([2H])c2c1[2H]]

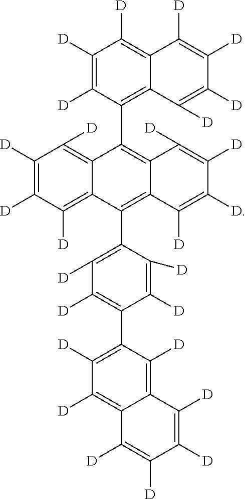

According to one embodiment of the present specification, the compound of Chemical Formula 3 is any one compound selected from among the following compounds:

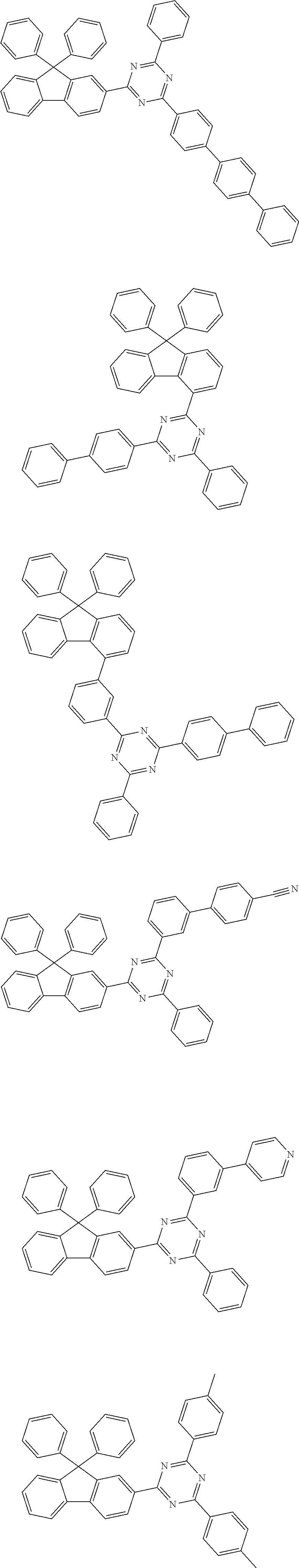

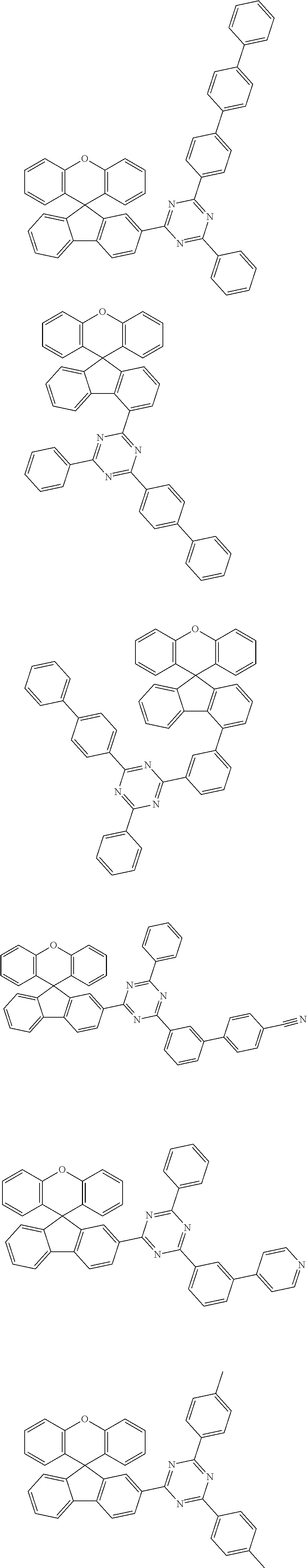

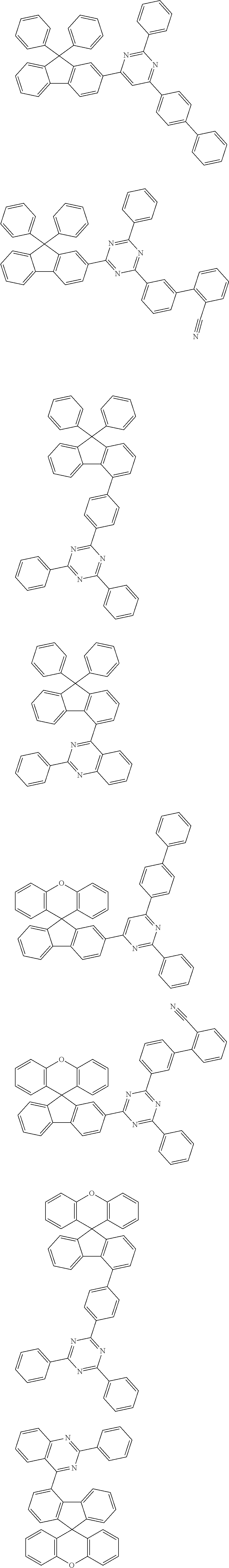

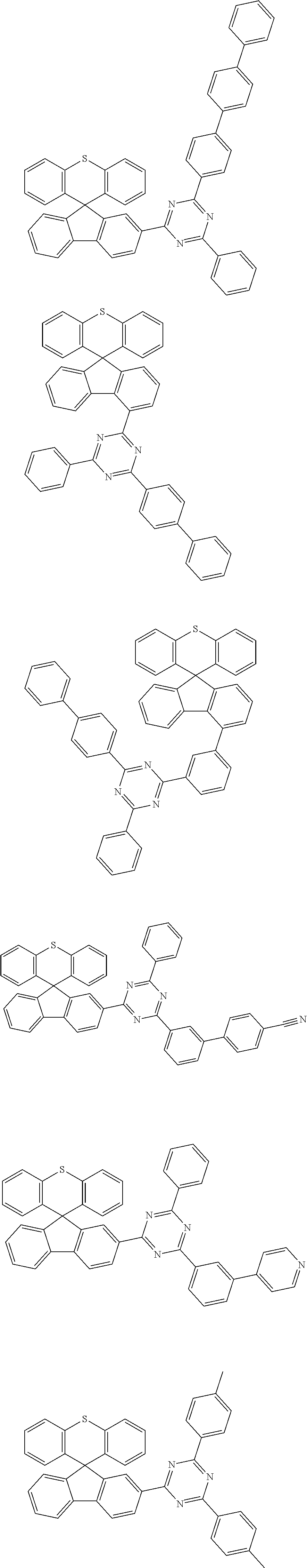

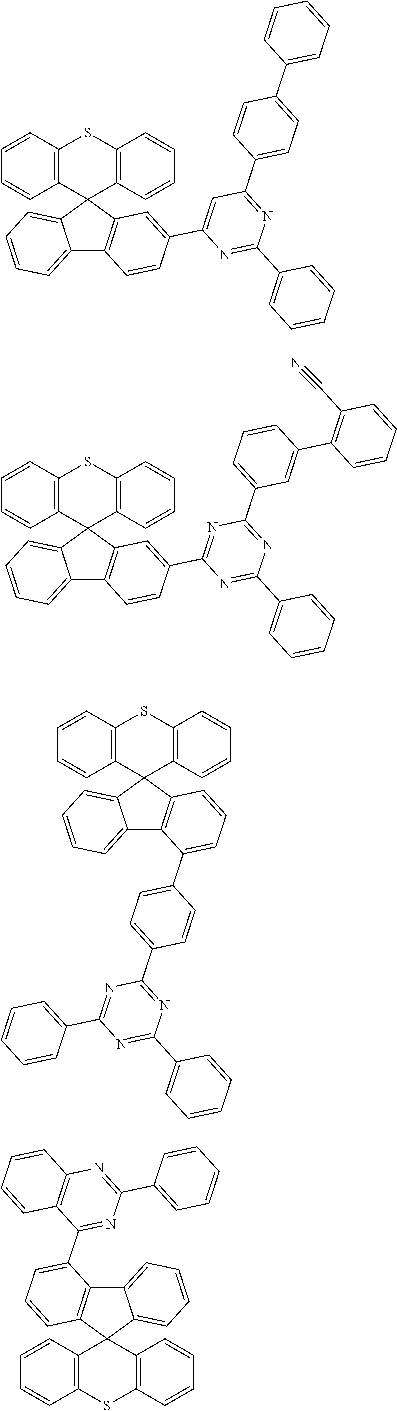

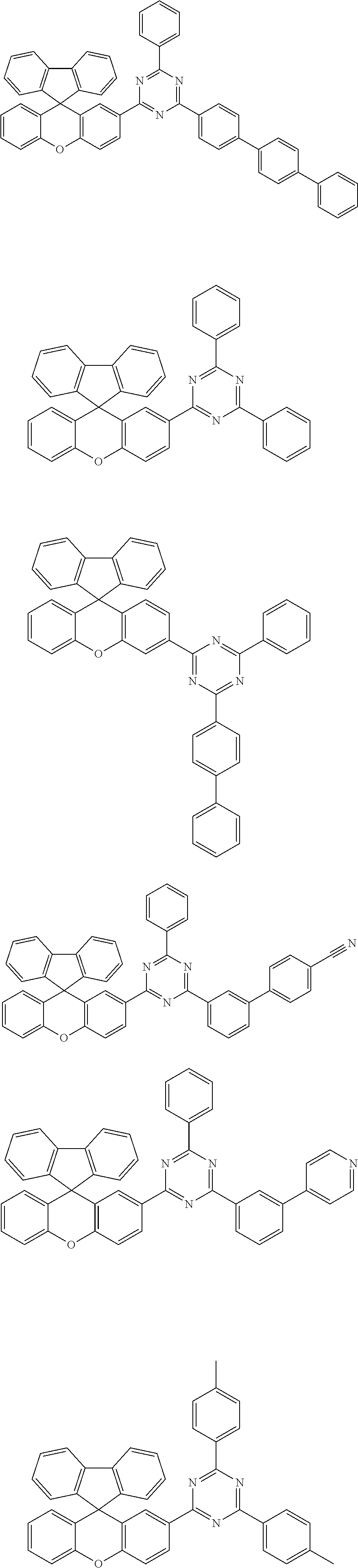

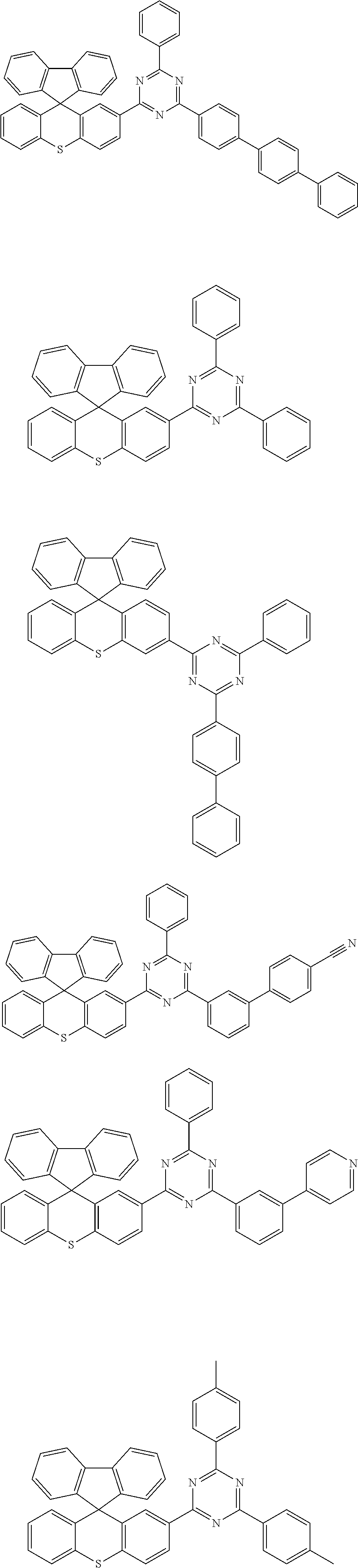

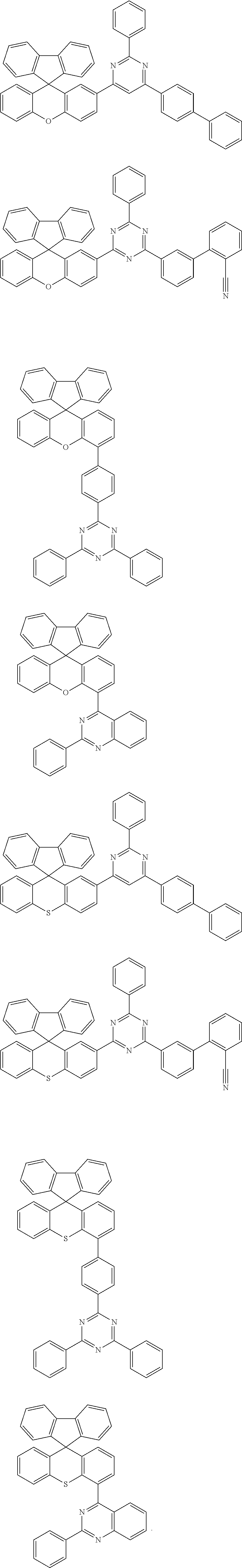

According to one embodiment of the present specification, the compounds of Chemical Formulae 1 to 3 can be prepared using starting materials and reaction conditions known in the art. Types and the number of substituents can be determined by those skilled in the art properly selecting known starting materials. In addition, commercially available materials can be purchased as the compounds of Chemical Formulae 1 to 3.

According to one embodiment of the present specification, the organic light emitting device can only include the first organic material layer described above, the second organic material layer and the light emitting layer described above as the organic material layer, but can further include an additional organic material layer. For example, additional hole injection layer, hole transfer layer, electron blocking layer, hole blocking layer, electron transfer layer, electron injection layer and the like can be further included.

According to one embodiment of the present specification, the organic light emitting device can further include an additional organic material layer. As the additional organic material layer, one or more of a hole injection layer, a hole transfer layer, a hole injection and transfer layer, an electron injection layer, an electron transfer layer, an electron injection and transfer layer, an electron control layer, an electron blocking layer, a hole blocking layer and a hole control layer can be included. However, the structure of the organic light emitting device is not limited thereto, and can include a smaller number of organic material layers.

In another embodiment, the organic light emitting device can be an organic light emitting device having a structure in which an anode, one or more organic material layers and a cathode are consecutively laminated on a substrate (normal type).

In another embodiment, the organic light emitting device can be an organic light emitting device having a structure in a reverse direction in which a cathode, one or more organic material layers and an anode are consecutively laminated on a substrate (inverted type).

When the organic light emitting device includes a plurality of organic material layers, the organic material layers can be formed with the same materials or different materials.

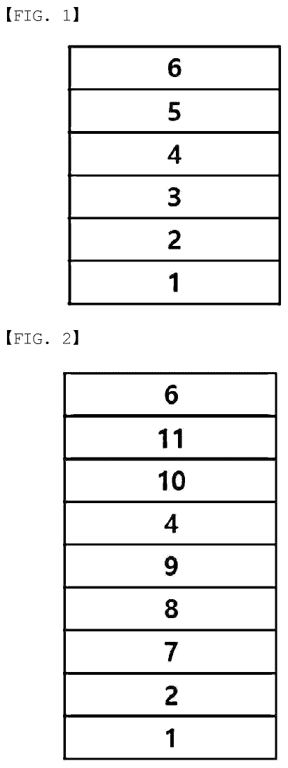

The organic light emitting device of the present specification can have structures as illustrated in, for example, FIG. 1 and FIG. 2, however, the structure is not limited thereto.

FIG. 1 illustrates a structure of the organic light emitting device in which an anode (2), a first organic material layer (3), a light emitting layer (4) and a second organic material layer (5) and a cathode (6) are consecutively laminated on a substrate (1). FIG. 1 shows an illustrative structure according to one embodiment of the present specification, and other organic material layers can be further included.

FIG. 2 illustrates a structure of the organic light emitting device in which an anode (2), a hole injection layer (7), a hole transfer layer (8), an electron blocking layer (9), a light emitting layer (4), a hole blocking layer (10), an electron injection and transfer layer (11) and a cathode (6) are consecutively laminated on a substrate (1). FIG. 2 shows an illustrative structure according to one embodiment of the present specification, and other organic material layers can be further included.

The organic light emitting device of the present specification can be manufactured using materials and methods known in the art, except that the first organic material layer includes the compound of Chemical Formula 1, the light emitting layer includes the compound of Chemical Formula 2, and the second organic material layer includes the compound of Chemical Formula 3.

For example, the organic light emitting device of the present specification can be manufactured by consecutively laminating an anode, an organic material layer and a cathode on a substrate. Herein, the organic light emitting device can be manufactured by forming an anode on a substrate by depositing a metal, a metal oxide having conductivity, or an alloy thereof using a physical vapor deposition (PVD) method such as sputtering or e-beam evaporation, and forming an organic material layer including a hole injection layer, a hole transfer layer, a light emitting layer and an electron transfer layer thereon, and then depositing a material usable as a cathode thereon. In addition to such a method, the organic light emitting device can also be manufactured by consecutively depositing a cathode material, an organic material layer and an anode material on a substrate.

In addition to such a method, the organic light emitting device can also be manufactured by consecutively laminating a cathode material, an organic material layer and an anode material on a substrate (International Patent Application Laid-Open Publication No. 2003/012890). However, the manufacturing method is not limited thereto.

As the anode material, materials having large work function are normally preferred so that hole injection to an organic material layer is smooth. Specific examples of the anode material that can be used in the present disclosure include metals such as vanadium, chromium, copper, zinc and gold, or alloys thereof; metal oxides such as zinc oxide, indium oxide, indium tin oxide (ITO) and indium zinc oxide (IZO); combinations of metals and oxides such as ZnO:Al or SnO₂:Sb; conductive polymers such as poly(3-methylthiophene), poly[3,4-(ethylene-1,2-dioxy)thiophene] (PEDOT), polypyrrole and polyaniline, but are not limited thereto.

As the cathode material, materials having small work function are normally preferred so that electron injection to an organic material layer is smooth. Specific examples of the cathode material include metals such as magnesium, calcium, sodium, potassium, titanium, indium, yttrium, lithium, gadolinium, aluminum, silver, tin and lead, or alloys thereof; multilayer structure materials such as LiF/Al, LiO₂/Al or Mg/Ag, and the like, but are not limited thereto.

On the cathode, a capping layer for electrode protection can be further formed, and as the capping layer material, those used in the art can be properly used.

The hole injection layer is a layer receiving holes from an electrode, and as the hole injection material, compounds having an ability to transfer holes and thereby having a hole injection effect from an anode and an excellent hole injection effect for a light emitting layer or a light emitting material, preventing excitons generated in the light emitting layer from moving to an electron injection layer or an electron injection material, and in addition thereto, having an excellent thin film forming ability are preferred. The highest occupied molecular orbital (HOMO) of the hole injection material is preferably in between the work function of an anode material and the HOMO of surrounding organic material layers. Specific examples of the hole injection material include metal porphyrins, oligothiophene, arylamine-based organic materials, hexanitrile hexaazatriphenylene-based organic materials, quinacridone-based organic materials, perylene-based organic materials, anthraquinone, polyaniline and polythiophene-based conductive polymers, and the like, but are not limited thereto.

The hole transfer layer is a layer receiving holes from a hole injection layer and transferring the holes to a light emitting layer, and as the hole transfer material, materials having, as a material capable of receiving holes from an anode or a hole injection layer and moving the holes to a light emitting layer, high mobility for the holes are suited. Specific examples thereof include arylamine-based organic materials, conductive polymers, block copolymers having conjugated parts and non-conjugated parts together, and the like, but are not limited thereto.

The electron blocking layer is a layer capable of enhancing lifetime and efficiency of a device by preventing holes injected from a hole injection layer from passing through a light emitting layer and entering an electron injection layer, and when the organic light emitting device according to one embodiment of the present specification includes an additional electron blocking layer in addition to the electron blocking layer including Chemical Formula 1, the additional electron blocking layer can be formed in a proper part between the light emitting layer and the electron injection layer using known materials.

An electron control layer can be further provided between the light emitting layer and the electron transfer layer. As a material of the electron control layer, materials used in the art can be properly used.

The electron transfer layer is a layer receiving electrons from an electron injection layer and transferring the electrons to a light emitting layer, and as the electron transfer material when the organic light emitting device according to one embodiment of the present specification includes an additional electron transfer layer in addition to the electron transfer layer including Chemical Formula 3, materials capable of favorably receiving electrons from a cathode, moving the electrons to a light emitting layer, and having high mobility for the electrons are suited. Specific examples thereof include Al complexes of 8-hydroxyquinoline; complexes including Alq₃; organic radical compounds; hydroxyflavon-metal complexes and the like, but are not limited thereto. The electron transfer layer can be used together with any desired cathode material as used in the art. Particularly, examples of the suitable cathode material are common materials having low work function and having an aluminum layer or a silver layer following. Specifically, cesium, barium, calcium, ytterbium and samarium are included, and in each case, an aluminum layer or a silver layer follows.

The electron injection layer is a layer injecting electrons from an electrode, and compounds having an electron transferring ability, having an electron injection effect from a cathode and an excellent electron injection effect for a light emitting layer or light emitting material, preventing excitons generated in the light emitting layer from moving to a hole injection layer, and in addition thereto, having an excellent thin film forming ability are preferred. Specific examples thereof include fluorenone, anthraquinodimethane, diphenoquinone, thiopyran dioxide, oxazole, oxadiazole, triazole, imidazole, perylene tetracarboxylic acid, fluorenylidene methane, anthrone or the like, and derivatives thereof, metal complex compounds, nitrogen-containing 5-membered ring derivatives, and the like, but are not limited thereto.

The metal complex compound includes 8-hydroxyquinolinato lithium, bis(8-hydroxyquinolinato)zinc, bis(8-hydroxyquinolinato)copper, bis(8-hydroxyquinolinato)-manganese, tris(8-hydroxyquinolinato)aluminum, tris(2-methyl-8-hydroxyquinolinato)aluminum, tris(8-hydroxyquinolinato)-gallium, bis(10-hydroxybenzo[h]quinolinato)beryllium, bis(10-hydroxybenzo[h]quinolinato)zinc, bis(2-methyl-8-quinolinato)-chlorogallium, bis(2-methyl-8-quinolinato)(o-cresolato)-gallium, bis(2-methyl-8-quinolinato)(1-naphtholato)aluminum, bis(2-methyl-8-quinolinato)(2-naphtholato)gallium and the like, but is not limited thereto.

The electron injection and transfer layer is a layer carrying out electron injection and transfer at the same time, and is a layer injecting electrons from an electrode and transferring the electrons to a light emitting layer. When an additional layer is provided in addition to the electron injection and transfer layer including Chemical Formula 3, the electron transfer layer material and the electron injection layer material described above can be combined and used.

The hole blocking layer is a layer blocking holes from reaching a cathode, and can be generally foiled under the same condition as the hole injection layer. Specific examples thereof can include oxadiazole derivatives, triazole derivatives, phenanthroline derivatives, BCP, aluminum complexes and the like, but are not limited thereto.

The organic light emitting device according to the present specification can be a top-emission type, a bottom-emission type or a dual-emission type depending on the materials used.

The structure according to one embodiment of the present specification can also be used in an organic electronic device including an organic solar cell, an organic photo conductor, an organic transistor and the like under a similar principle used in the organic light emitting device.

### EXAMPLES

Manufacture of the organic light emitting device will be specifically described in the following examples. However, the following examples are for illustrative purposes only, and the scope of the present specification is not limited thereto.

### Manufacture of Organic Light Emitting Device

### Comparative Example 1

A patterned ITO substrate was used as an anode, a hole injection layer (100 Å) was formed on the ITO substrate with the following compounds HT1 and HI1 using a vacuum deposition method, and on the hole injection layer, a hole transfer layer (1150 Å) was formed with the following compound HT1. The following compound HTL_A was deposited to a thickness of 50 Å thereon as an electron blocking layer, and the following compounds Host_A and BD were deposited to a thickness of 200 Å in a volume ratio of 1% to 5% thereon as a light emitting layer, and the following compound HBL was deposited to a thickness of 50 Å as a hole blocking layer.

On the hole blocking layer, the following compounds ETL_A and LiQ were co-deposited to a thickness of 310 Å in a mass ratio of 5:5 as an electron injection and transfer layer.

On the electron injection and transfer layer, Mg:Ag (10%) were co-deposited to a thickness of 120 Å and then Al was deposited to 1000 Å as a cathode.

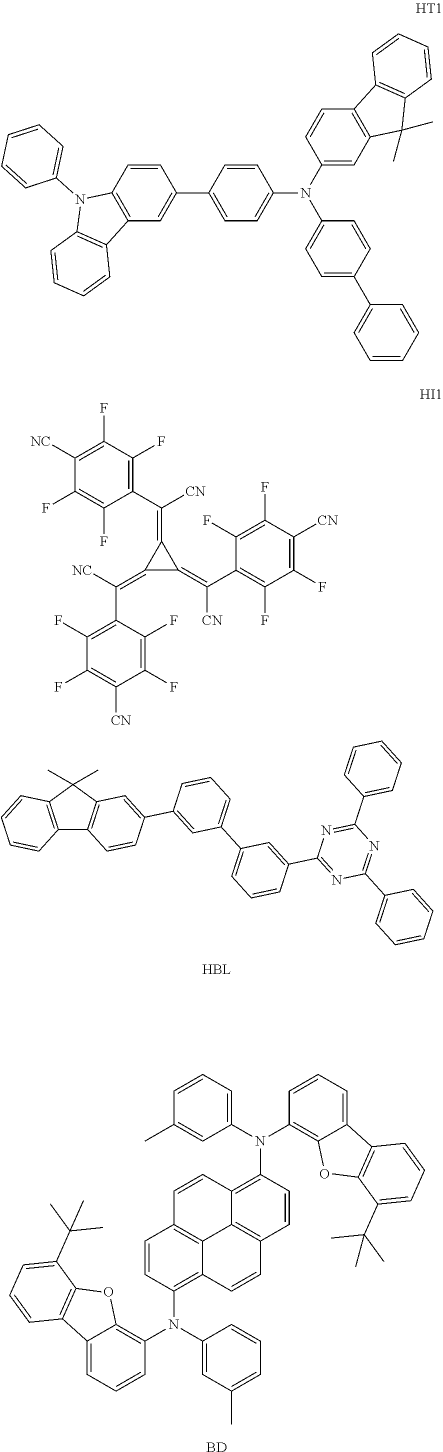

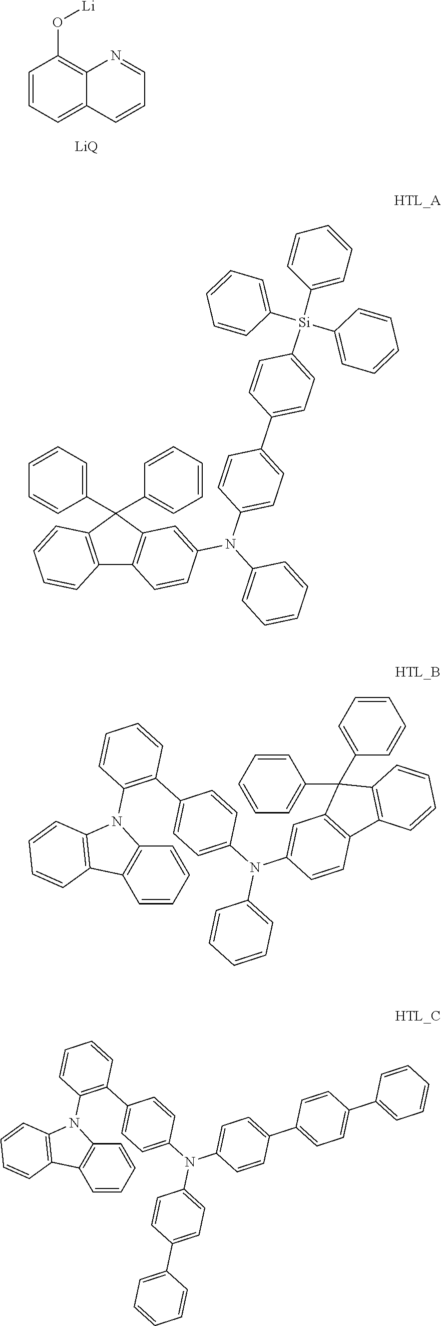

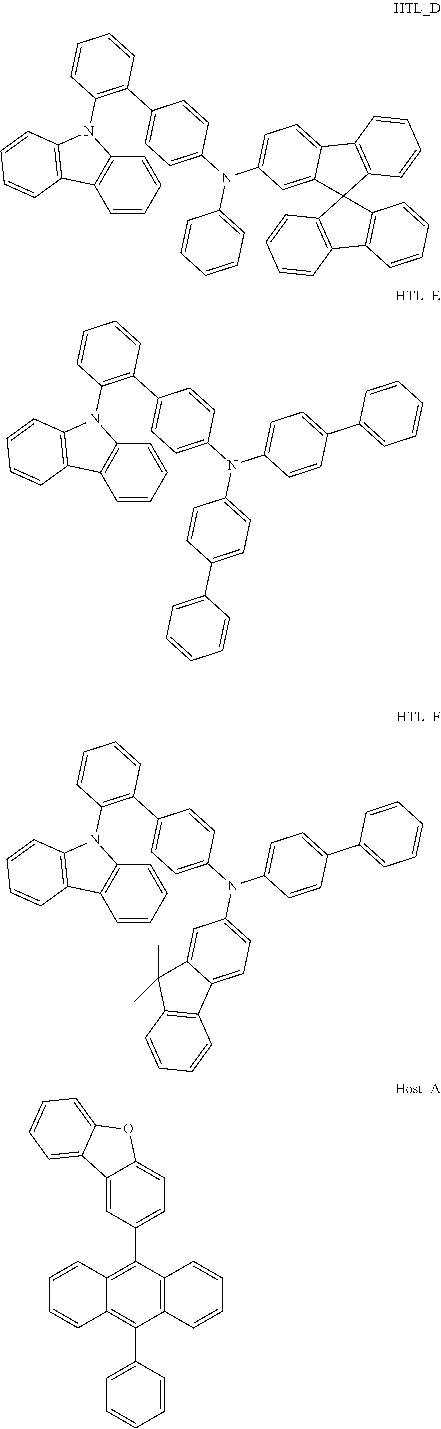 [SMILES: c1ccc(N(c2ccc(-c3ccccc3-n3c4ccccc4c4ccccc43)cc2)c2ccc3c(c2)C2(c4ccccc4-c4ccccc42)c2ccccc2-3)cc1 ; c1ccc(-c2ccc(N(c3ccc(-c4ccccc4)cc3)c3ccc(-c4ccccc4-n4c5ccccc5c5ccccc54)cc3)cc2)cc1 ; CC1(C)c2ccccc2-c2ccc(N(c3ccc(-c4ccccc4)cc3)c3ccc(-c4ccccc4-n4c5ccccc5c5ccccc54)cc3)cc21 ; c1ccc(-c2c3ccccc3c(-c3ccc4oc5ccccc5c4c3)c3ccccc23)cc1]

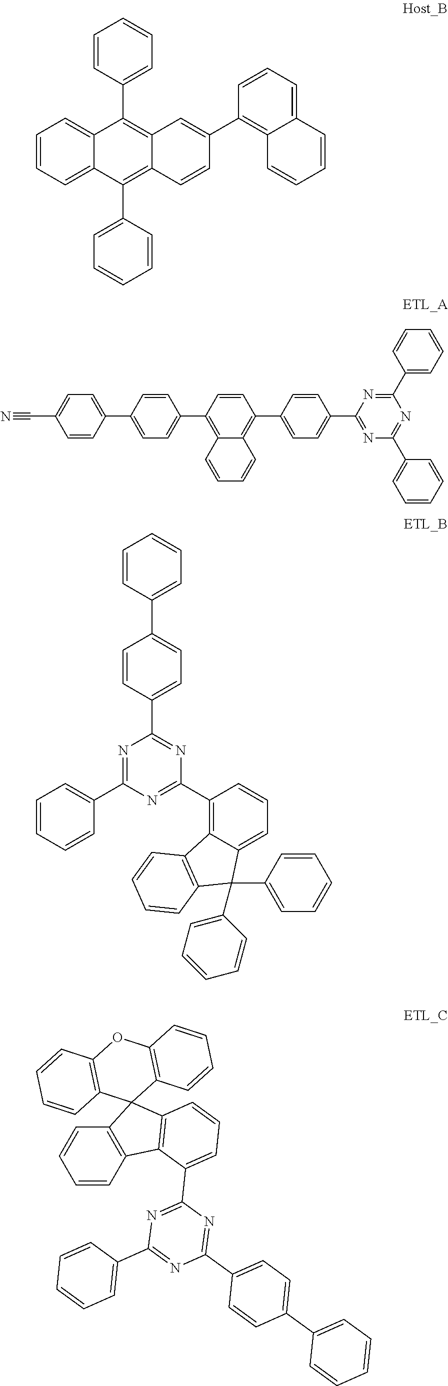

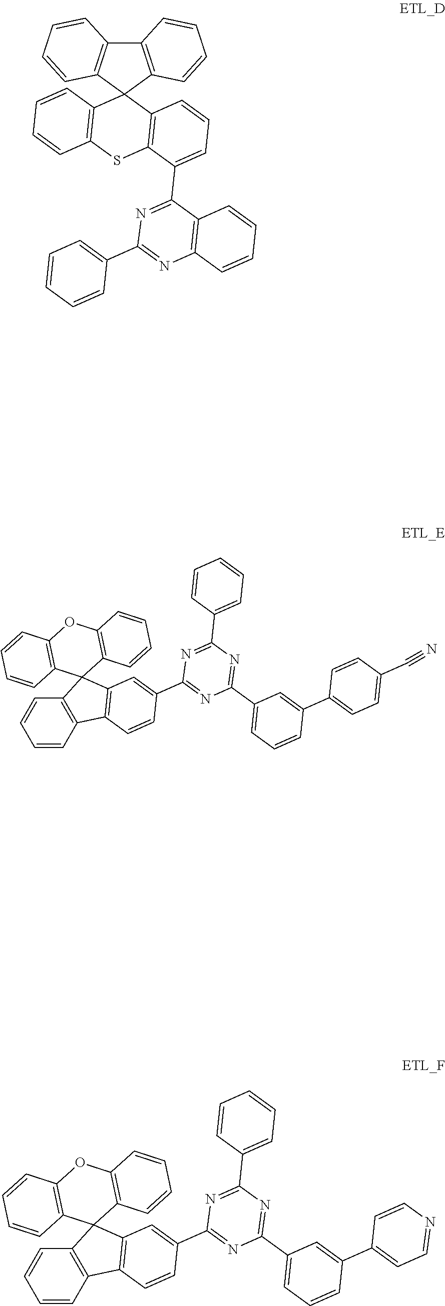 [SMILES: c1ccc(-c2nc(-c3cccc4c3Sc3ccccc3C43c4ccccc4-c4ccccc43)c3ccccc3n2)cc1 ; N#Cc1ccc(-c2cccc(-c3nc(-c4ccccc4)nc(-c4ccc5c(c4)C4(c6ccccc6Oc6ccccc64)c4ccccc4-5)n3)c2)cc1 ; c1ccc(-c2nc(-c3cccc(-c4ccncc4)c3)nc(-c3ccc4c(c3)C3(c5ccccc5Oc5ccccc53)c3ccccc3-4)n2)cc1]

### Comparative Examples 2 to 6 and Examples 1 to 13

Organic light emitting devices of Comparative Examples 2 to 6 and Examples 1 to 13 were manufactured in the same manner as in Comparative Example 1 except that compounds of the following Table 1 were used as the electron blocking layer instead of compound HTL_A, compounds of the following Table 1 were used instead of compound Host_A of the light emitting layer, compounds of the following Table 1 were used instead of compound ETL_A of the electron injection and transfer layer.

For Comparative Examples 1 to 6 and Examples 1 to 13, driving voltage and light emission efficiency were measured at current density of 10 mA/cm², and the results are shown in the following Table 1.

TABLE 1

| | | | Electron | | |
|---|---|---|---|---|---|
| | | Light | Injection | | Light |
| | Electron | Emitting | and | Driving | Emission |
| | Blocking | Layer | Transfer | Voltage | Efficiency |
| # | Layer | Host | Layer | (V) | (Cd/A) |
| Comparative | HTL_A | Host_A | ETL_A | 3.74 | 7 |
| Example 1 | | | | | |
| Comparative | HTL_D | Host_A | ETL_A | 3.75 | 6.82 |
| Example 2 | | | | | |
| Comparative | HTL_E | Host_A | ETL_A | 3.74 | 7.12 |
| Example 3 | | | | | |
| Comparative | HTL_F | Host_A | ETL_A | 3.78 | 6.92 |
| Example 4 | | | | | |
| Comparative | HTL_A | Host_A | ETL_E | 3.81 | 7.02 |
| Example 5 | | | | | |
| Comparative | HTL_A | Host_A | ETL_F | 3.8 | 6.8 |
| Example 6 | | | | | |
| Example 1 | HTL_B | Host_B | ETL_B | 3.78 | 7.77 |
| Example 2 | HTL_B | Host_B | ETL_C | 3.75 | 7.92 |
| Example 3 | HTL_B | Host_B | ETL_D | 3.76 | 8.02 |
| Example 4 | HTL_C | Host_B | ETL_B | 3.83 | 7.85 |
| Example 5 | HTL_C | Host_B | ETL_C | 3.78 | 7.78 |
| Example 6 | HTL_C | Host_B | ETL_D | 3.8 | 8.01 |
| Example 7 | HTL_D | Host_B | ETL_B | 3.82 | 7.82 |
| Example 8 | HTL_D | Host_B | ETL_E | 3.79 | 8.15 |
| Example 9 | HTL_B | Host_B | ETL_E | 3.81 | 8.04 |
| Example 10 | HTL_C | Host_B | ETL_F | 3.77 | 7.98 |
| Example 11 | HTL_E | Host_B | ETL_C | 3.81 | 7.68 |
| Example 12 | HTL_F | Host_B | ETL_E | 3.76 | 7.97 |
| Example 13 | HTL_E | Host_B | ETL_E | 3.8 | 8.06 |

From the results of Table 1, it was identified that the organic light emitting device according to one embodiment of the present specification including Chemical Formula 1 in the electron blocking layer, including Chemical Formula 2 as the host of the light emitting layer, and including Chemical Formula 3 in the electron injection and transfer layer had superior light emission efficiency compared to the organic light emitting device including each of Chemical Formulae 1 to 3, or only two materials of Chemical Formulae 1 to 3.

Calculation of Energy Level

LUMO energy level, singlet energy and triplet energy of Compound HTL_A to Compound HTL_F and Compound ETL_A to Compound ETL_F are shown in the following Table 2.

TABLE 2

| | LUMO (eV) | Singlet Energy (eV) | Triplet Energy (eV) |
|---|---|---|---|
| HTL_A | −1.96 | 3.3 | 2.56 |
| HTL_B | −1.98 | 3.29 | 2.56 |
| HTL_C | −2.04 | 3.28 | 2.63 |
| HTL_D | −1.98 | 3.29 | 2.58 |
| HTL_E | −1.99 | 3.36 | 2.69 |
| HTL_F | −1.99 | 3.27 | 2.59 |
| ETL_A | −2.92 | 3.33 | 2.40 |
| ETL_B | −2.80 | 3.41 | 2.72 |
| ETL_C | −2.85 | 3.38 | 2.74 |
| ETL_D | −2.71 | 3.46 | 2.48 |
| ETL_E | −2.98 | 3.21 | 2.55 |
| ETL_F | −2.77 | 3.28 | 2.57 |

In Table 2, the LUMO energy level, the singlet energy and the triplet energy of the compound of Chemical Formula 1 and the compound of Chemical Formula 3 used in Examples 1 to 13 of the present specification were calculated using Gaussian 03, a quantum chemistry calculation program developed by Gaussian, Inc. of the USA, and using a density functional theory (DFT), the calculated value of the triplet energy was obtained using a time dependent density functional theory (TD-DFT) for the optimized structure using B3LYP as a function and 6-31G* as a basis function.

Compound HTL_B to Compound HTL_F and Compound ETL_B to Compound ETL_F of Table 2 satisfied one or more of Equation 1 to Equation 3, and it was identified that the organic light emitting device had superior efficiency as in Table 1.

1. An organic light emitting device comprising:
an anode;
a cathode;
a light emitting layer provided between the anode and the cathode;
a first organic material layer provided between the light emitting layer and the anode; and
a second organic material layer provided between the light emitting layer and the cathode,
wherein the first organic material layer includes a compound of the following Chemical Formula 1;
the light emitting layer includes a compound of the following Chemical Formula 2;
the second organic material layer includes a compound of the following Chemical Formula 3; and
Chemical Formula 1 and Chemical Formula 3 satisfy any one or more of the following <Equation 1> to <Equation 3>: 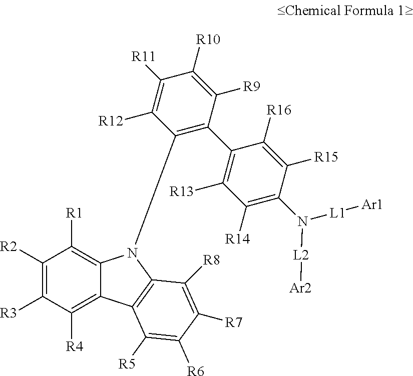
wherein in Chemical Formula 1:
L1 and L2 are the same as or different from each other, and each independently is a direct bond or a substituted or unsubstituted arylene group;
Ar1 and Ar2 are the same as or different from each other, and each independently is deuterium, a halogen group, a cyano group, a substituted or unsubstituted alkyl group, a substituted or unsubstituted cycloalkyl group, a substituted or unsubstituted silyl group or a substituted or unsubstituted aryl group; and
R1 to R16 are the same as or different from each other, and each independently is hydrogen; or deuterium, or adjacent groups among R1 to R8 bond to each other to form a substituted or unsubstituted ring; 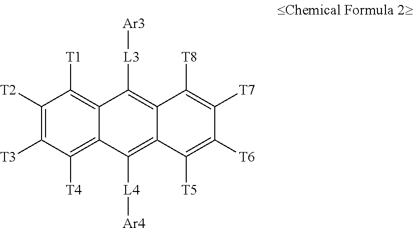
wherein in Chemical Formula 2:
L3 and L4 are the same as or different from each other, and each independently is a direct bond or a substituted or unsubstituted arylene group;
Ar3 and Ar4 are the same as or different from each other, and each independently is deuterium or a substituted or unsubstituted aryl group; and
T1 to T8 are the same as or different from each other, and each independently is hydrogen, deuterium, or a substituted or unsubstituted aryl group; 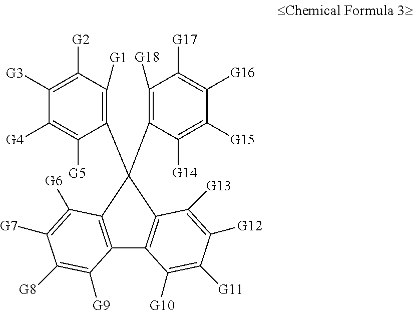
wherein in Chemical Formula 3;
at least one of G1 to G18 is -L5-Ar5, and the rest are hydrogen, or G1 and G18 are linked through -L51- to form a substituted or unsubstituted ring;
L5 is a direct bond or a substituted or unsubstituted arylene group;
Ar5 is a substituted or unsubstituted aryl group or a substituted or unsubstituted heteroaryl group; and
L51 is O or S;

|E_{L1}<E_{L3}| <Equation 1>
Eₛ₁>Eₛ₃ <Equation 2>
E_{T1}>E_{T3} <Equation 3>
wherein in Equations 1 to 3:
E_{L1} means a LUMO energy level (eV) of the compound of Chemical Formula 1;
E_{L3} means a LUMO energy level (eV) of the compound of Chemical Formula 3;
Eₛ₁ means a singlet energy (eV) of the compound of Chemical Formula 1;
Eₛ₃ means a singlet energy (eV) of the compound of Chemical Formula 3;
E_{T1} means a triplet energy (eV) of the compound of Chemical Formula 1; and
E_{T3} means a triplet energy (eV) of the compound of Chemical Formula 3.

2. The organic light emitting device of claim 1, wherein the first organic material layer is in contact with the light emitting layer.

3. The organic light emitting device of claim 1, wherein the light emitting layer includes a fluorescent dopant.

4. The organic light emitting device of claim 1, wherein the light emitting layer is a single layer.

5. The organic light emitting device of claim 1, wherein the light emitting layer is a blue light emitting layer.

6. The organic light emitting device of claim 1, which has a maximum emission wavelength (λₘₐₓ) of 400 nm to 470 nm in a light emission spectrum.

7. The organic light emitting device of claim 1, wherein the light emitting layer further includes a compound different from the compound of Chemical Formula 2.

8. The organic light emitting device of claim 1, comprising one or more additional organic material layers between the second organic material layer and the light emitting layer.

9. The organic light emitting device of claim 1, wherein the second organic material layer includes the compound of Chemical Formula 3, an organic alkali metal complex compound, or a mixture thereof.

10. The organic light emitting device of claim 1, wherein Ar5 is any one selected from among the following structures: 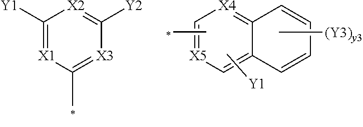
wherein in the structures;
* is a site bonding to L5 of Chemical Formula 3;
at least one of X1 to X3 is N, and the rest are CH;
at least one of X4 and X5 is N, and any remaining is CH;
Y1 to Y3 are the same as or different from each other, and each independently is hydrogen, deuterium, a substituted or unsubstituted alkyl group, a substituted or unsubstituted aryl group or a substituted or unsubstituted heteroaryl group; and
y3 is an integer of 1 to 4, and when y3 is 2 or greater, the two or more Y3s are the same as or different from each other.

11. The organic light emitting device of claim 1, wherein the compound of Chemical Formula 1 is any one compound selected from among the following compounds:

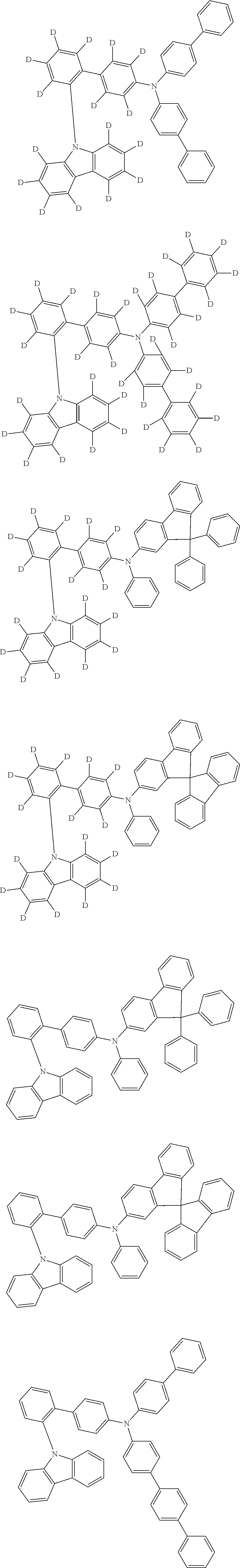

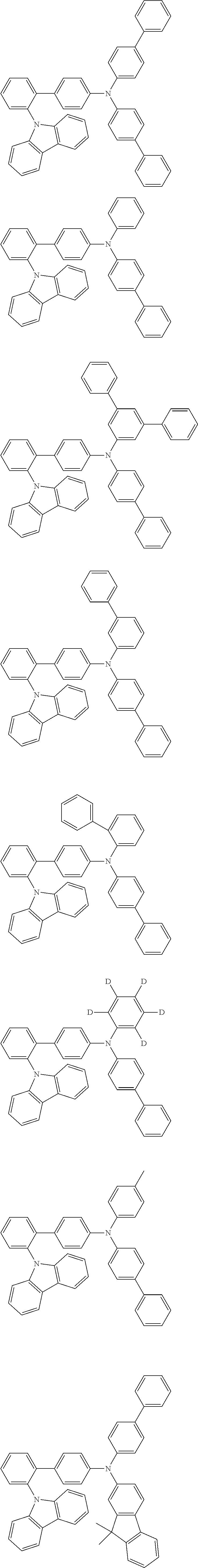

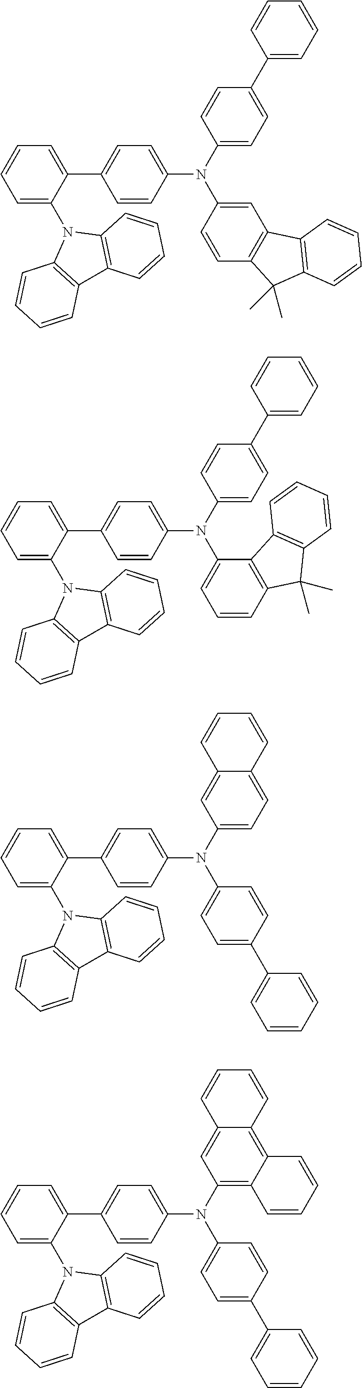

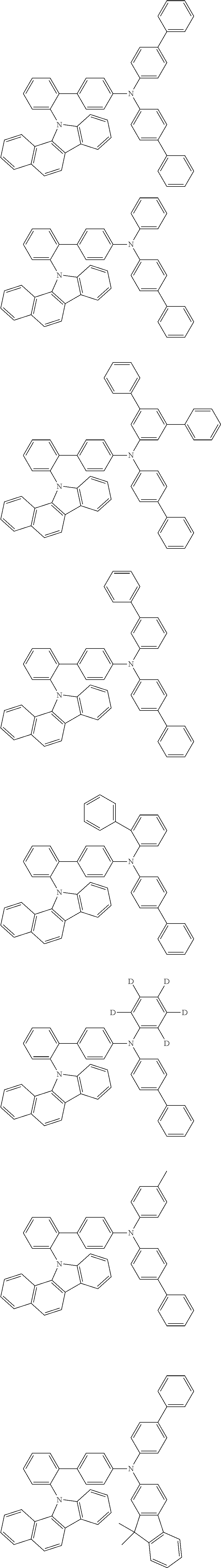

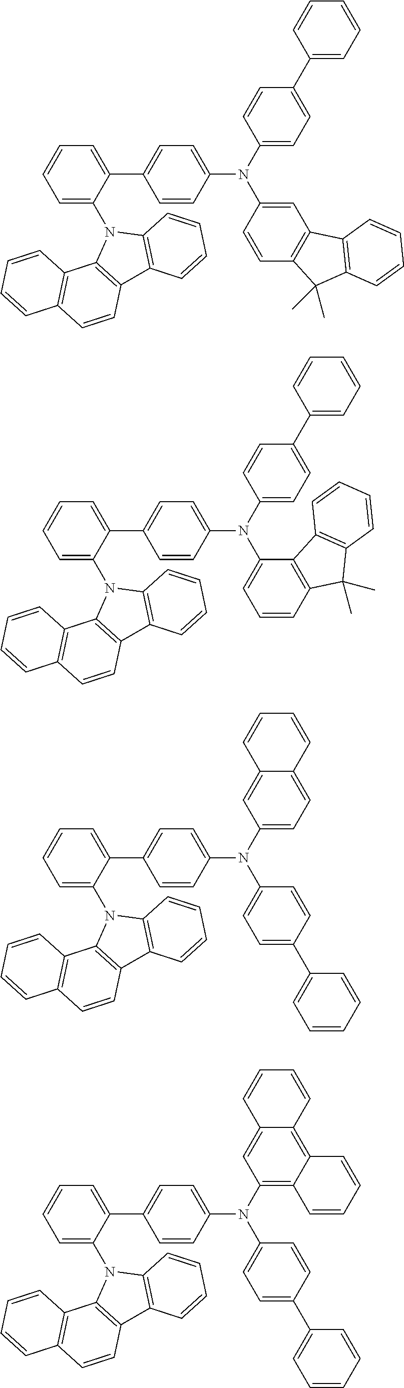

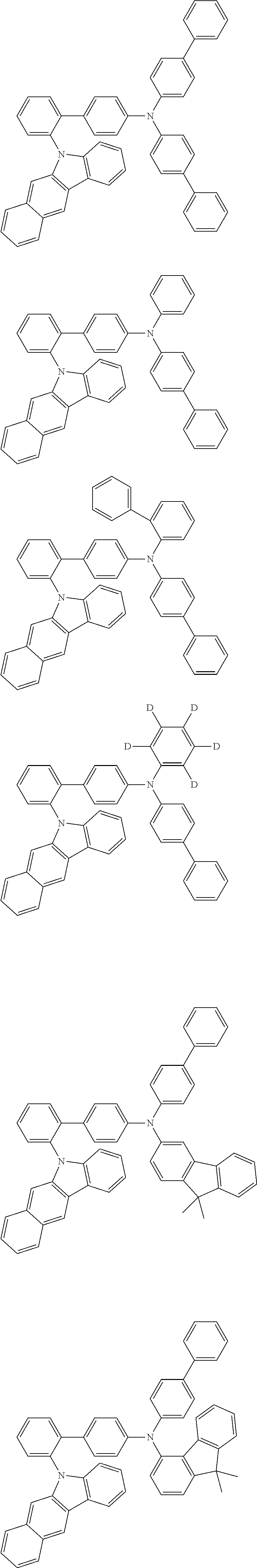

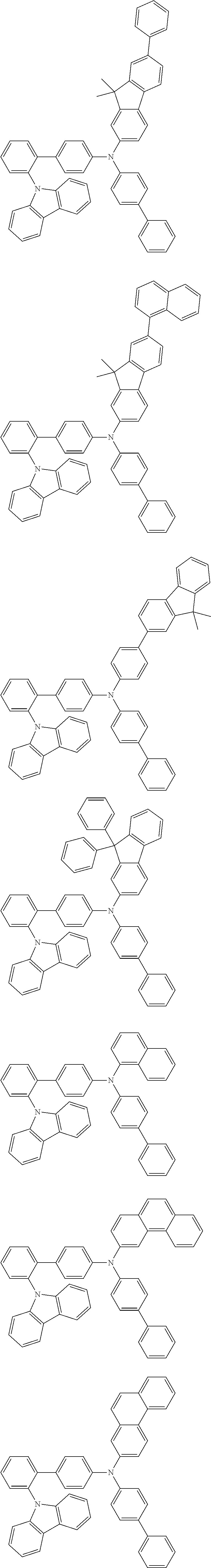

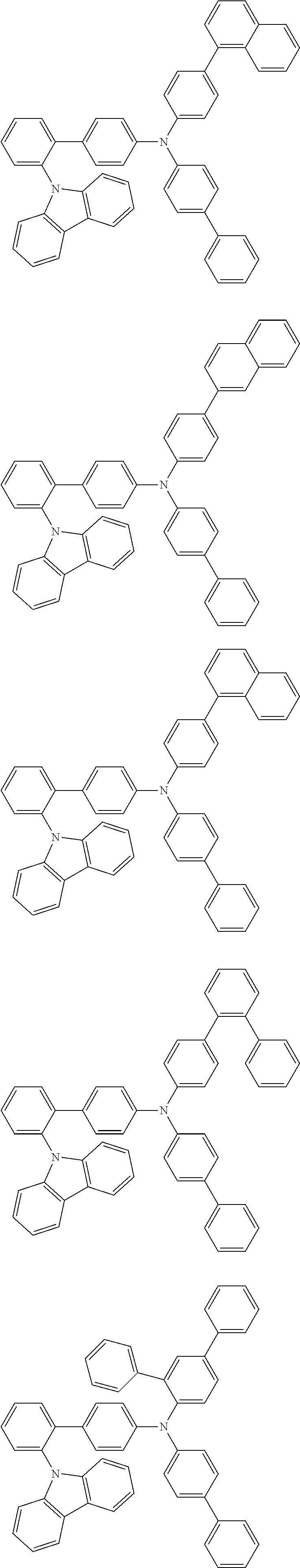

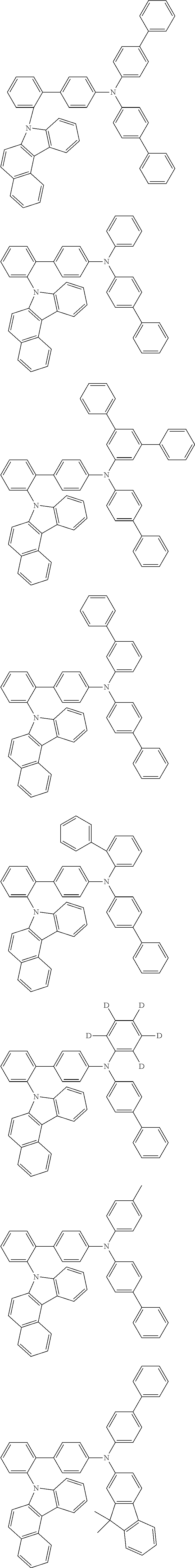

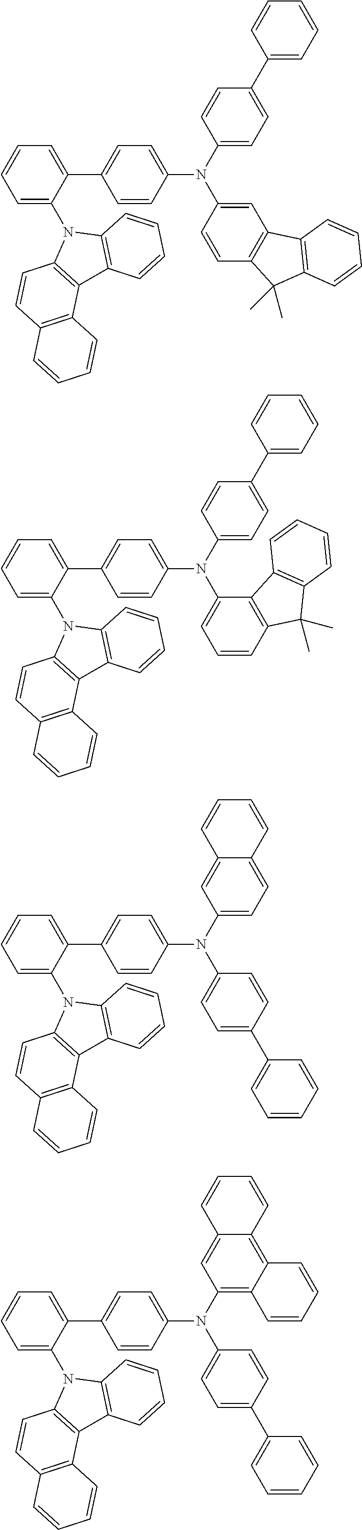 [SMILES: CC1(C)c2ccccc2-c2cc(N(c3ccc(-c4ccccc4)cc3)c3ccc(-c4ccccc4-n4c5ccccc5c5c6ccccc6ccc54)cc3)ccc21 ; CC1(C)c2ccccc2-c2c(N(c3ccc(-c4ccccc4)cc3)c3ccc(-c4ccccc4-n4c5ccccc5c5c6ccccc6ccc54)cc3)cccc21 ; c1ccc(-c2ccc(N(c3ccc(-c4ccccc4-n4c5ccccc5c5c6ccccc6ccc54)cc3)c3ccc4ccccc4c3)cc2)cc1 ; c1ccc(-c2ccc(N(c3ccc(-c4ccccc4-n4c5ccccc5c5c6ccccc6ccc54)cc3)c3cc4ccccc4c4ccccc34)cc2)cc1]

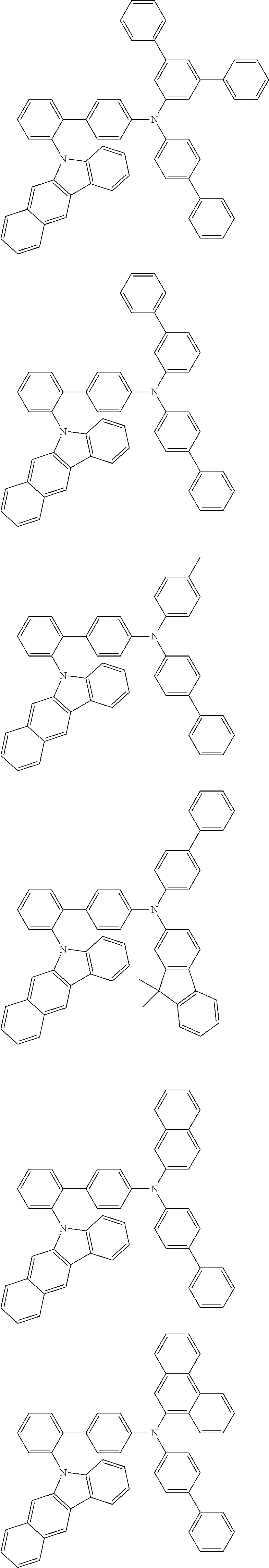

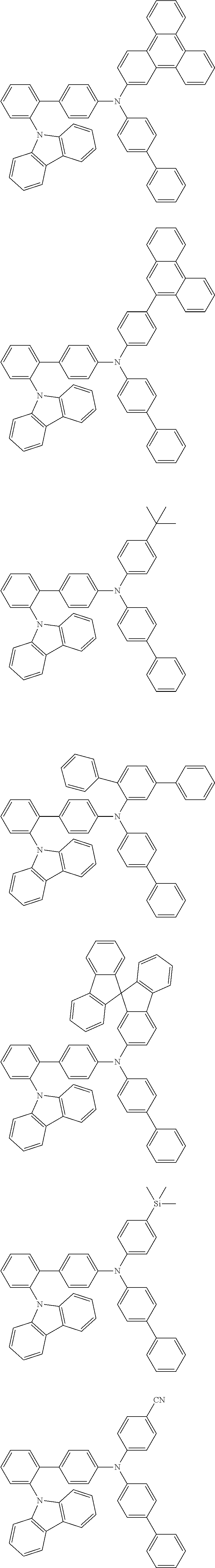

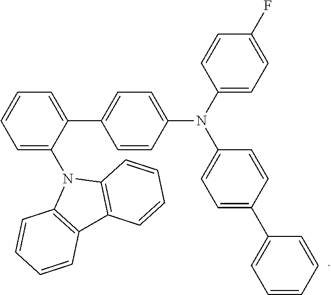 [SMILES: Fc1ccc(N(c2ccc(-c3ccccc3)cc2)c2ccc(-c3ccccc3-n3c4ccccc4c4ccccc43)cc2)cc1]

12. The organic light emitting device of claim 1, wherein the compound of Chemical Formula 2 is any one compound selected from among the following compounds:

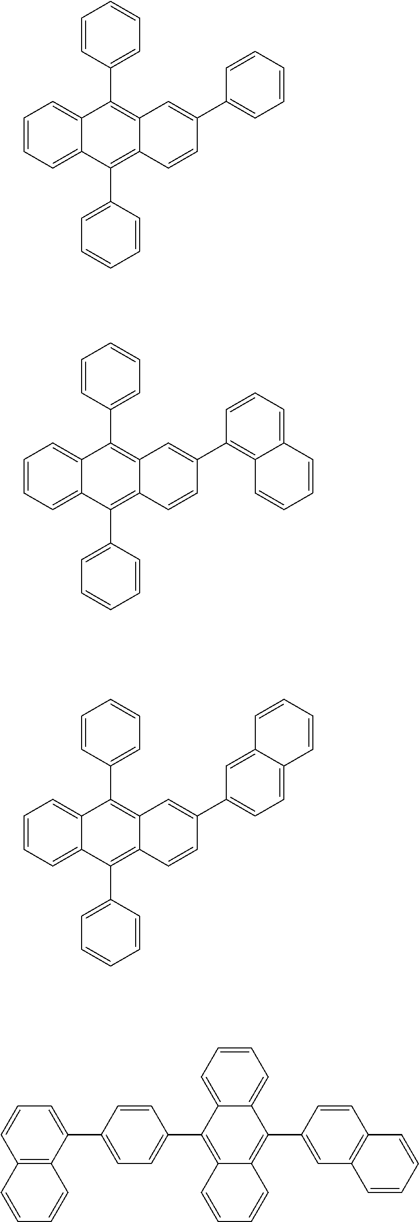

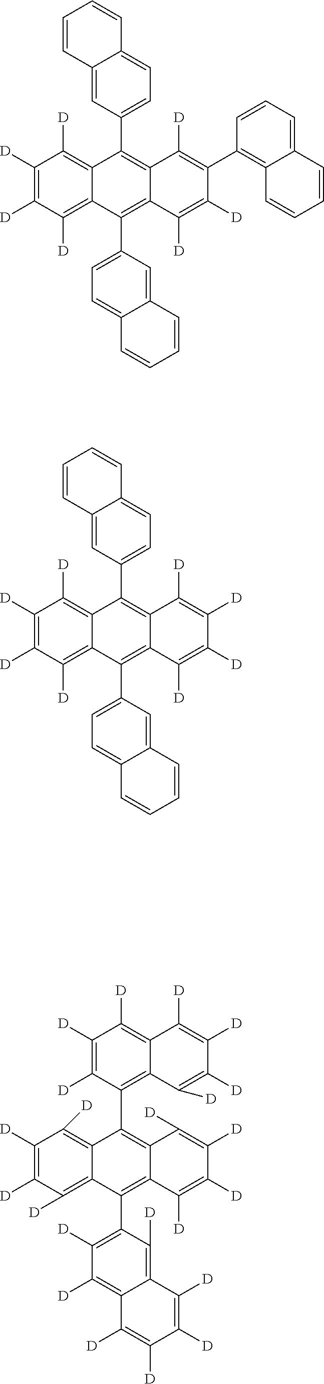 [SMILES: [2H]c1c([2H])c([2H])c2c(-c3ccc4ccccc4c3)c3c([2H])c(-c4cccc5ccccc45)c([2H])c([2H])c3c(-c3ccc4ccccc4c3)c2c1[2H] ; [2H]c1c([2H])c([2H])c2c(-c3ccc4ccccc4c3)c3c([2H])c([2H])c([2H])c([2H])c3c(-c3ccc4ccccc4c3)c2c1[2H] ; [2H]c1c([2H])c([2H])c2c([2H])c(-c3c4c([2H])c([2H])c([2H])c([2H])c4c(-c4c([2H])c([2H])c([2H])c5c([2H])c([2H])c([2H])c([2H])c45)c4c([2H])c([2H])c([2H])c([2H])c34)c([2H])c([2H])c2c1[2H]]

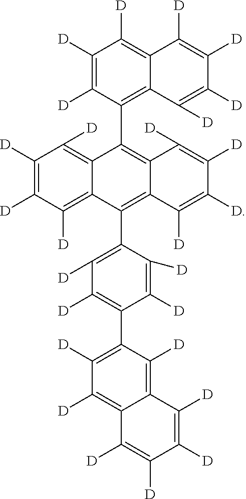

13. The organic light emitting device of claim 1, wherein the compound of Chemical Formula 3 is any one compound selected from among the following compounds: 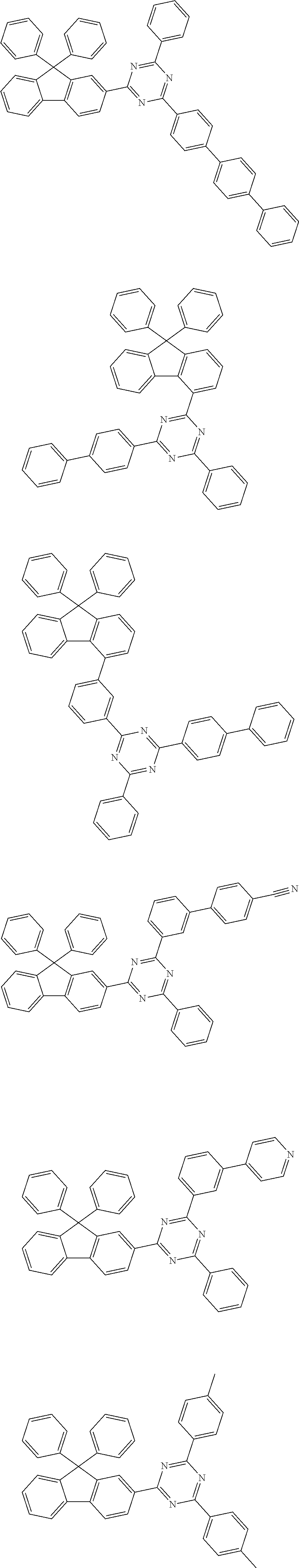 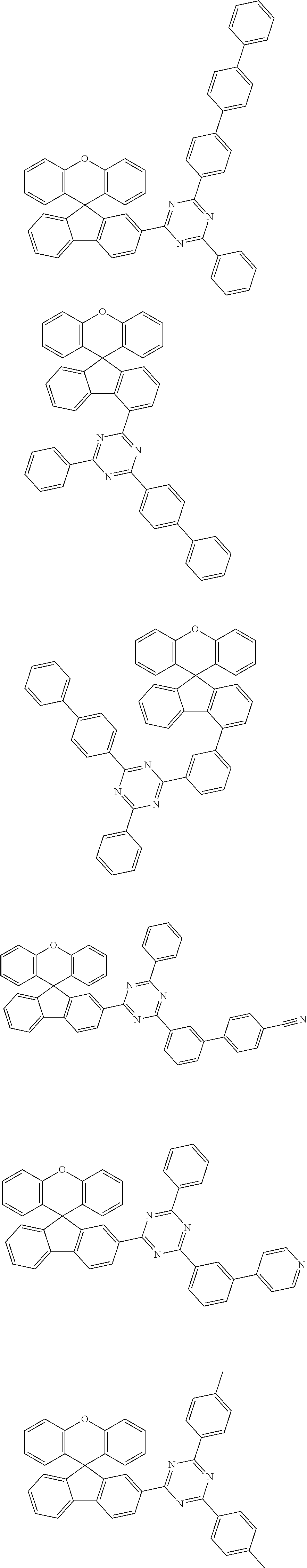 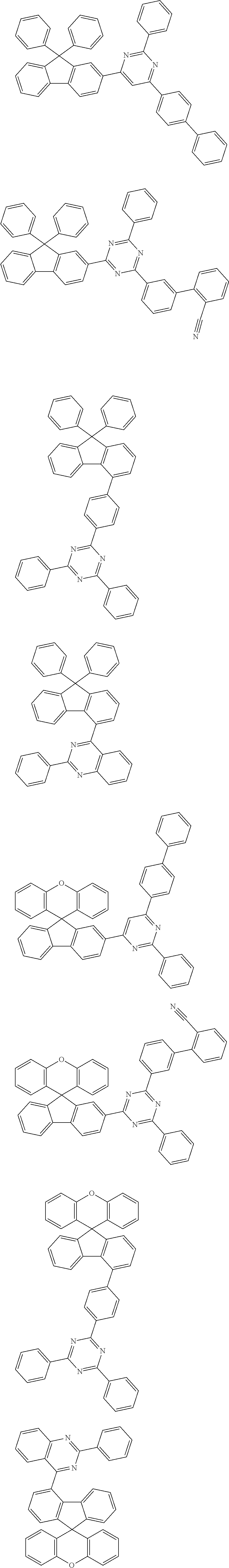 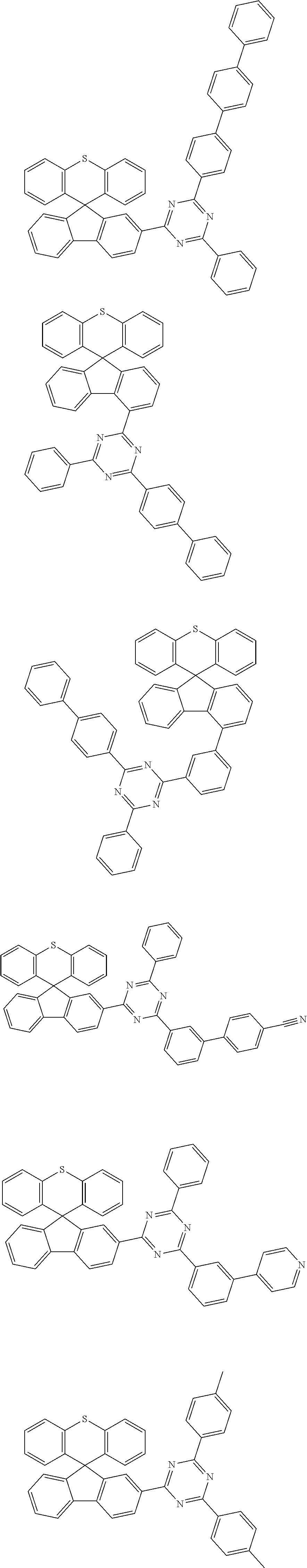 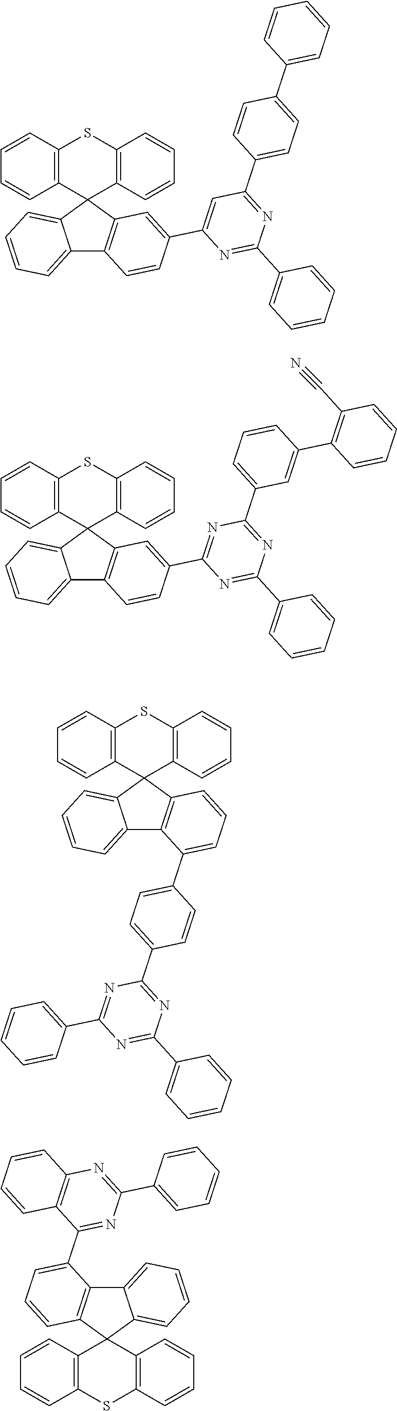 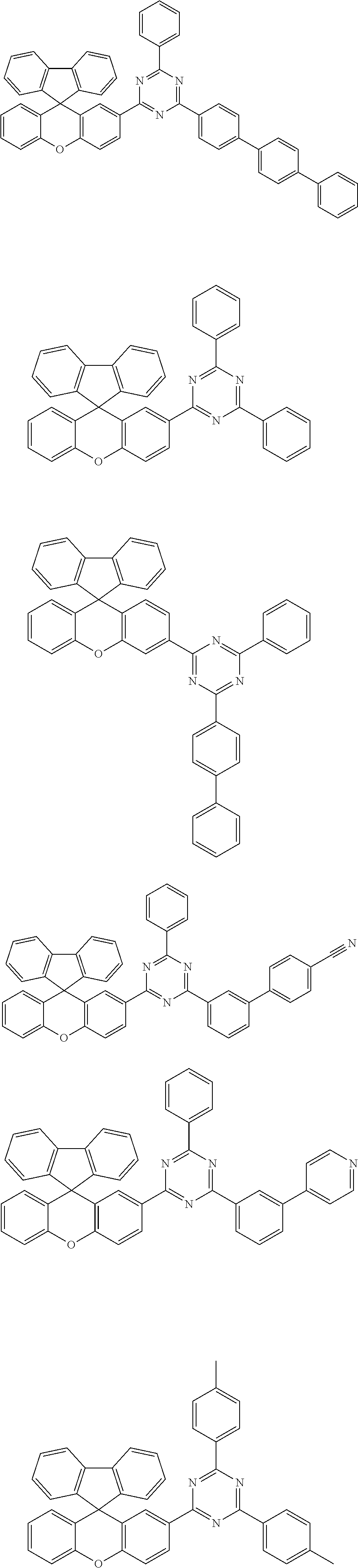 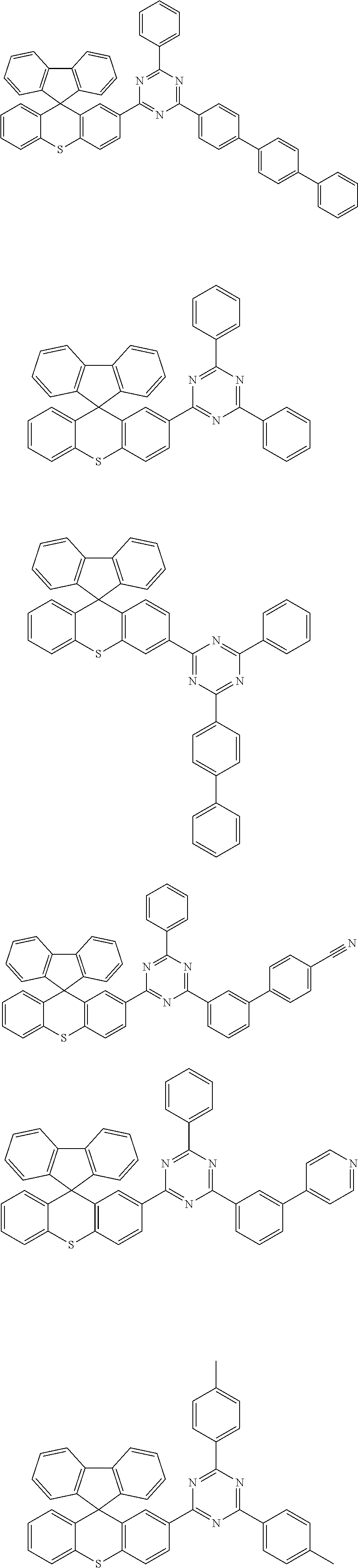 [chemical structure]
